(19) United States
(12) Patent Application Publication
(10) Pub. No.: US 2025/0336677 A1
(43) Pub. Date: Oct. 30, 2025

(54) Etch Stop Region for Semiconductor Device Substrate Thinning

(71) Applicant: Taiwan Semiconductor Manufacturing Co., Ltd., Hsinchu (TW)

(72) Inventors: Bau-Ming Wang, Kaohsiung City (TW); Liang-Yin Chen, Hsinchu (TW); Wei Tse Hsu, Zhubei City (TW); Jung-Tsan Tsai, New Taipei City (TW); Ya-Ching Tseng, Hsinchu (TW); Chunyii Liu, Hsinchu (TW)

(21) Appl. No.: 19/260,545

(22) Filed: Jul. 6, 2025

Related U.S. Application Data
(63) Continuation of application No. 18/152,454, filed on Jan. 10, 2023.
(60) Provisional application No. 63/374,807, filed on Sep. 7, 2022.

(51) Int. Cl. H01L 21/225; H01L 21/306; H01L 21/311; H10D 30/43; H10D 30/67; H10D 62/10; H10D 64/01; H10D 84/01; H10D 84/03; H10D 84/85

(52) U.S. Cl. CPC H01L 21/2253; H01L 21/30625; H10D 30/6729; H10D 64/01; H10D 84/0186; H10D 84/038; H10D 84/85; H01L 21/31144; H10D 30/43; H10D 30/6735; H10D 30/6757; H10D 62/121; H10D 64/017; H10D 64/021; H10D 84/0167; H10D 84/0188

(57) ABSTRACT

A method includes implanting impurities in a semiconductor substrate to form an etch stop region within the semiconductor substrate; forming a transistor structure on a front side of the semiconductor substrate; forming a front-side interconnect structure over the transistor structure; performing a thinning process on a back side of the semiconductor substrate to reduce a thickness of the semiconductor substrate, wherein the thinning process is slowed by the etch stop region; and forming a back-side interconnect structure over the back side of the semiconductor substrate.

### CROSS-REFERENCE TO RELATED APPLICATIONS

This application is a continuation of U.S. patent application Ser. No. 18/152,454, filed on Jan. 10, 2023, which claims the benefit of U.S. Provisional Application No. 63/374,807, filed on Sep. 7, 2022, each application is hereby incorporated herein by reference.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example of a nanostructure field-effect transistor (nano-FET) in a three-dimensional view, in accordance with some embodiments.

FIGS. 2, 3, 4, 5, 6, 7, 8, 9, 10A, 10B, 10C, 11A, 11B, 11C, 12A, 12B, 12C, 13A, 13B, 13C, 14A, 14B, 14C, 15A, 15B, 15C, 15D, 16A, 16B, 16C, 16D, 16E, 17A, 17B, 17C, 18A, 18B, 18C, 19A, 19B, 19C, 20A, 20B, 20C, 21A, 21B, 21C, 22A, 22B, 22C, 23A, 23B, 23C, 24A, 24B, 24C, 25A, 25B, 25C, 26A, 26B, 26C, 27A, 27B, 27C, 28A, 28B, 28C, 29A, 29B, 29C, 30A, 30B, and 30C are cross-sectional views of intermediate stages in the manufacturing of nano-FETs, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Various embodiments provide semiconductor devices and methods of forming the same. The semiconductor devices may include a front-side interconnect structure (also referred to as a back end of line (BEOL) interconnect structure) and a backside interconnect structure (also referred to as a buried power network (BPN)) on opposite sides of a device layer (such as a device layer including transistor structures). Providing the backside interconnect structure may reduce the number of layers required for the front-side interconnect structure, and the backside interconnect structure may have wider lines than the front-side interconnect structure, both of which provide improved speed performance and energy efficiency. In various embodiments, an etch stop region may be formed in the substrate, which stops or slows the removal of backside substrate material during a thinning process (e.g., a chemical mechanical polish (CMP) process or the like) performed prior to forming the backside interconnect structure. The etch stop region may be formed by implanting a region of impurities in the substrate, and may be followed by an anneal to reduce implantation defects. Stopping or slowing the thinning process in this manner can reduce dishing or pattern loading effects, and can improve the planarity of the thinned surface. In this manner, forming an etch stop region as described herein can improve planarity during substrate thinning, which can improve the quality of subsequently-performed lithographic steps, improve device uniformity, and improve device yield.

Embodiments are described below in a particular context, namely, a die comprising nanostructure field-effect transistors (nano-FETs). Various embodiments may be applied, however, to dies comprising other types of transistors (e.g., fin field effect transistors (FinFETs), planar transistors, or the like) in lieu of or in combination with the nano-FETs.

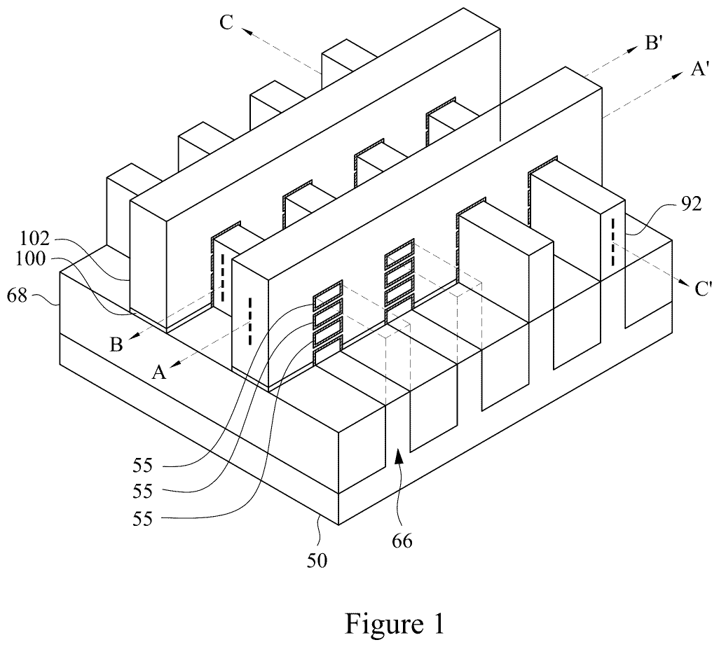

FIG. 1 illustrates an example of nano-FETs (e.g., nanowire FETs, nanosheet FETs (Nano-FETs), or the like) in a three-dimensional view, in accordance with some embodiments. The nano-FETs comprise nanostructures 55 (e.g., nanosheets, nanowires, or the like) over fins 66 on a substrate 50 (e.g., a semiconductor substrate). The nanostructures 55 act as channel regions for the nano-FETs. The nanostructures 55 may include p-type nanostructures, n-type nanostructures, or a combination thereof. Isolation regions 68 are disposed between adjacent fins 66, which may protrude above and from between neighboring isolation regions 68. Although the isolation regions 68 are described and illustrated as being separate from the substrate 50, as used herein, the term “substrate” may refer to the semiconductor substrate alone or a combination of the semiconductor substrate and the isolation regions. Additionally, although bottom portions of the fins 66 are illustrated as being single, continuous materials with the substrate 50, the bottom portions of the fins 66 and/or the substrate 50 may comprise a single material or a plurality of materials. In this context, the fins 66 refer to the portion extending between the neighboring isolation regions 68.

Gate dielectric layers 100 are over top surfaces and sidewalls of the fins 66 and along top surfaces, sidewalls, and bottom surfaces of the nanostructures 55. Gate electrodes 102 are over the gate dielectric layers 100. Epitaxial source/drain regions 92 are disposed on the fins 66 on opposing sides of the gate dielectric layers 100 and the gate electrodes 102. Source/drain region(s) may refer to a source or a drain, individually or collectively dependent upon the context.

FIG. 1 further illustrates reference cross-sections that are used in later figures. Cross-section A-A′ is along a longitudinal axis of a gate electrode 102 and in a direction, for example, perpendicular to the direction of current flow between epitaxial source/drain regions 92 of a nano-FET. Cross-section B-B′ is parallel to cross-section A-A′ and extends through epitaxial source/drain regions 92 of multiple nano-FETs. Cross-section C-C′ is perpendicular to cross-section A-A′ and is parallel to a longitudinal axis of a fin 66 of the nano-FET and in a direction of, for example, a current flow between the epitaxial source/drain regions 92 of the nano-FET. Subsequent figures refer to these reference cross-sections for clarity.

Some embodiments discussed herein are discussed in the context of nano-FETs formed using a gate-last process. In some embodiments, a gate-first process may be used. Also, some embodiments contemplate aspects which may be used in planar devices, such as planar FETs, or in fin field-effect transistors (FinFETs).

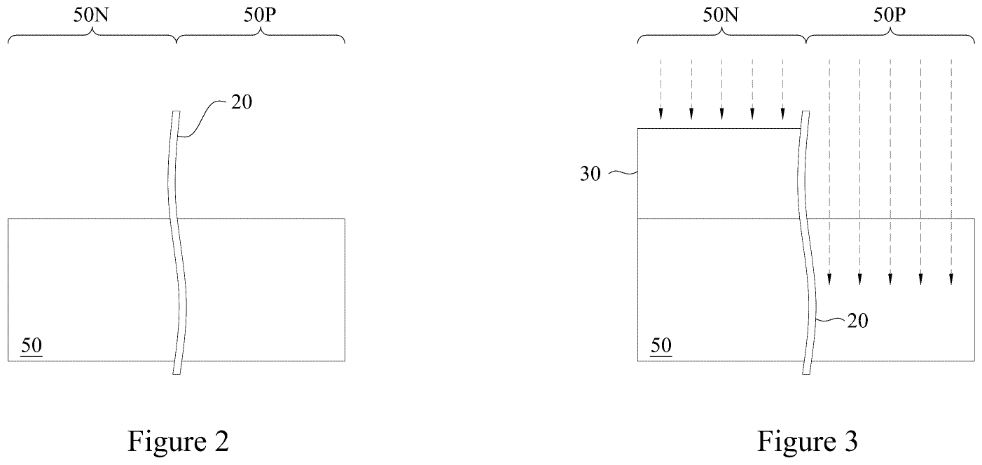

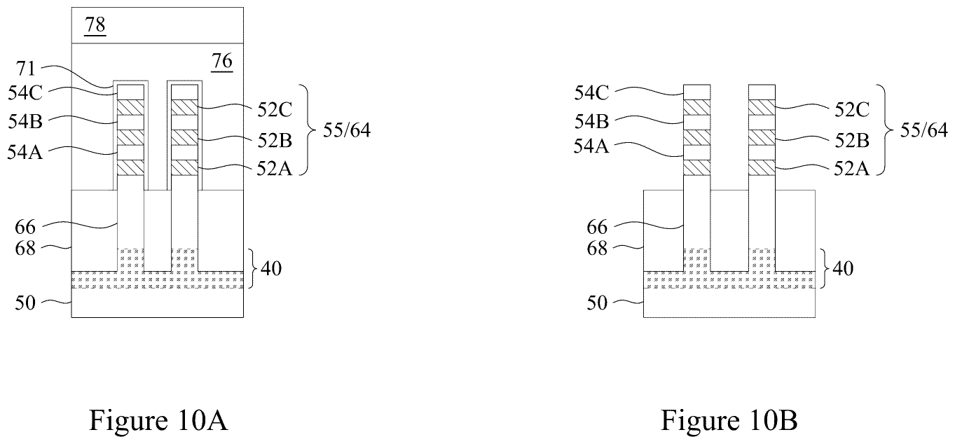

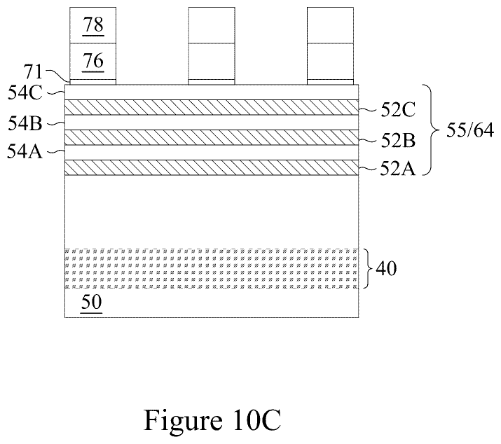

FIGS. 2 through 30C are cross-sectional views of intermediate stages in the manufacturing of nano-FETs, in accordance with some embodiments. FIGS. 2 through 9, 10A, 11A, 12A, 13A, 14A, 15A, 16A, 17A, 18A, 19A, 20A, 21A, 22A, 23A, 24A, 25A, 26A, 27A, 28A, 29A, and 30A are illustrated along reference cross-section A-A′ indicated in FIG. 1. FIGS. 10B, 11B, 12B, 13B, 14B, 15B, 16B, 16D, 17B, 18B, 19B, 20B, 21B, 22B, 23B, 24B, 25B, 26B, 27B, 28B, 29B, and 30B are illustrated along reference cross-section B-B′ indicated in FIG. 1. FIGS. 10C, 11C, 12C, 13C, 14C, 15C, 15D, 16C, 16E, 17C, 18C, 19C, 20C, 21C, 22C, 23C, 24C, 25C, 26C, 27C, 28C, 29C, and 30C are illustrated along reference cross-section C-C′ indicated in FIG. 1.

In FIG. 2, a substrate 50 is provided. The substrate 50 may be a semiconductor substrate, such as a bulk semiconductor, a semiconductor-on-insulator (SOI) substrate, or the like, which may be doped (e.g., with a p-type or an n-type dopant) or un-doped. The substrate 50 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 50 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof. A pad oxide (not shown) may be present on a top surface of the substrate 50, in some cases.

The substrate 50 has an n-type region 50N and a p-type region 50P. The n-type region 50N can be for forming n-type devices, such as NMOS transistors, e.g., n-type nano-FETs. The p-type region 50P can be for forming p-type devices, such as PMOS transistors, e.g., p-type nano-FETs. The n-type region 50N may be physically separated from the p-type region 50P (as illustrated by divider 20), and any number of device features (e.g., other active devices, doped regions, isolation structures, or the like) may be disposed between the n-type region 50N and the p-type region 50P. Although one n-type region 50N and one p-type region 50P are illustrated, any number of n-type regions 50N and p-type regions 50P may be provided.

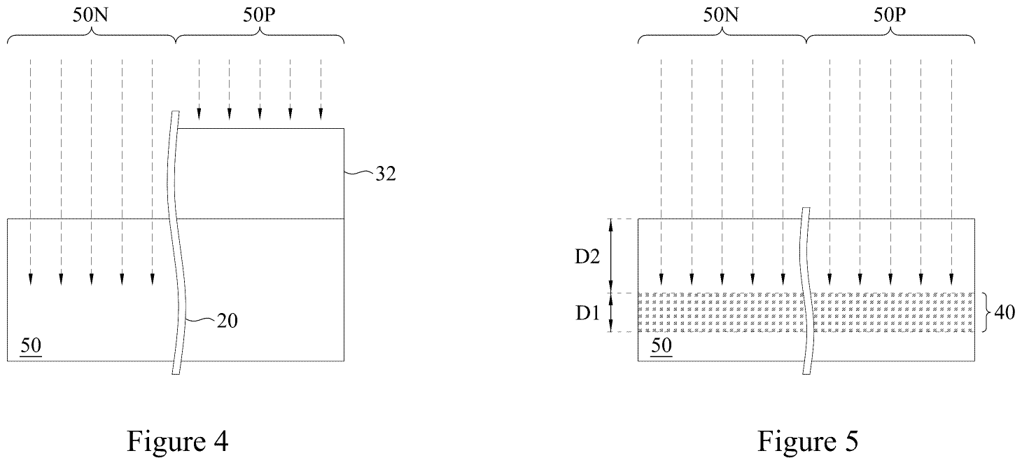

In FIGS. 3 and 4, appropriate wells (not shown) are formed in the n-type region 50N and the p-type region 50P of the substrate 50, in accordance with some embodiments. In some embodiments, a P-well may be formed in the n-type region 50N, and an N-well may be formed in the p-type region 50P. In some embodiments, a P well or an N well are formed in both the n-type region 50N and the p-type region 50P. In the embodiments with different well types, the different implant steps for the n-type region 50N and the p-type region 50P may be achieved using a photoresist and/or other masks. After the implanting of the n-type region 50N and the p-type region 50P, an anneal may be performed to repair implant damage and to activate the p-type and/or n-type impurities that were implanted.

As an example, FIG. 3 illustrates the implanting of the p-type region 50P, in accordance with some embodiments. A photoresist 30 may be formed over the substrate 50 and patterned to expose the p-type region 50P of the substrate 50. The photoresist 30 can be formed by using a spin-on technique and can be patterned using acceptable photolithography techniques. Once the photoresist 30 is patterned, an n-type impurity implant is performed in the p-type region 50P, and the photoresist 30 may act as a mask to substantially prevent n-type impurities from being implanted into the n-type region 50N. The n-type impurities may be phosphorus, arsenic, antimony, the like, or a combination thereof implanted in the region to a concentration of equal to or less than about 10¹⁸ cm⁻³, such as in the range of about 10¹⁶ c⁻³ to about 10¹⁸ cm⁻³. After the implant, the photoresist 30 is removed, such as by an acceptable ashing process.

FIG. 4 illustrates the implanting of the n-type region 50N, in accordance with some embodiments. Following the implanting of the p-type region 50P, a photoresist 32 is formed over the substrate 50 and patterned to expose the n-type region 50N of the substrate 50. The photoresist 32 can be formed by using a spin-on technique and can be patterned using acceptable photolithography techniques. Once the photoresist 32 is patterned, a p-type impurity implant may be performed in the n-type region 50N, and the photoresist 32 may act as a mask to substantially prevent p-type impurities from being implanted into the p-type region 50P. The p-type impurities may be boron, boron fluoride, indium, or the like implanted in the region to a concentration of equal to or less than about 10¹⁸ cm⁻³, such as in the range of about 10¹⁶ cm⁻³ to about 10¹⁸ cm⁻³. After the implant, the photoresist 32 may be removed, such as by an acceptable ashing process.

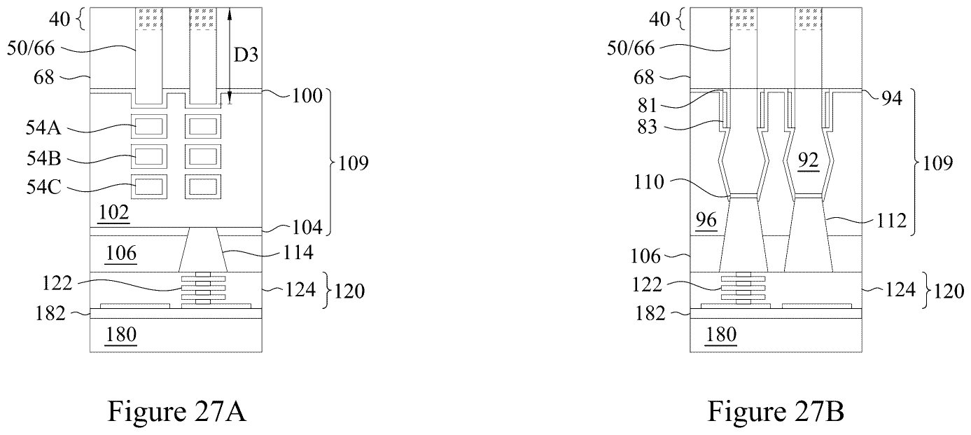

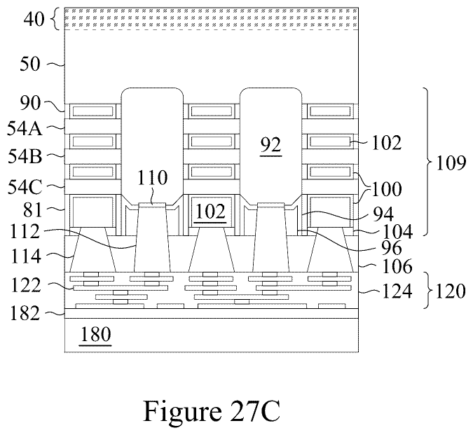

In FIG. 5, an implantation process is performed to form an etch stop region 40 in the substrate 50, in accordance with some embodiments. The etch stop region 40 may be formed to improve the planarity of a thinning process subsequently performed on the substrate 50, described in greater detail below for FIGS. 27A-27C. The implantation process may implant impurities such as boron, aluminum, gallium, indium, titanium, the like, or a combination thereof into the substrate 50. Other impurities are possible. In some embodiments, the etch stop region 40 may have a impurity concentration in the range of about 10¹⁸ cm⁻³ to about 10²⁰ cm⁻³, though other concentrations are possible. For example, in some embodiments, the etch stop region 40 may be formed by implanting boron into the substrate 50 to a concentration greater than about 5×10¹⁸ cm⁻³, though other impurities and/or impurity concentrations are possible.

In some embodiments, the implantation energy may be in the range of about 20 keV to about 40 keV, though other energies are possible. In some embodiments, the dosage may be in the range of about 5×10¹⁴ cm⁻² to about 1×10¹⁵ cm⁻², though other dosages are possible. In some embodiments, the implantation process may implant the impurities at an angle to reduce deep penetration into the substrate 50. For example, in some embodiments, the implantation process may comprise a tilt angle of about 7° and a twist angle of about 22°, though other angles are possible. In some embodiments, the implantation process may comprise a process temperature in the range of about 50° C. to about 500° C., though other temperatures are possible. In some cases, a greater process temperature may reduce implant damage, reduce the creation of defects in subsequently-formed features, and/or further improve the planarity after thinning the substrate 50.

In some embodiments, the etch stop region 40 may be formed by implanting impurities using multiple implantation processes. The multiple implantation processes may comprise different doses, energies, temperatures, etc. For example, in some embodiments, the etch stop region 40 may be formed by performing a first implantation process having an energy in the range of about 15 keV to about 25 keV and then performing a second implantation process having an energy in the range of about 35 keV to about 40 keV. This is an example, and other implantation parameters or combination of different implantation parameters are possible. In some cases, the use of multiple implantation processes can form an etch stop region 40 that more smoothly reduces the removal rate of the substrate 50 thinning process, described in greater detail below.

In some embodiments, an annealing process may be performed after the implantation process(es). The annealing process may repair implant damage, in some cases. The annealing process may comprise an annealing temperature in the range of about 700° C. to about 1200° C. or an annealing time in the range of about 1 second to about 2 seconds, though other annealing parameters are possible. In some embodiments, the annealing process for the etch stop region 40 is combined with an anneal for a P-well and/or an N-well, such as those described previously.

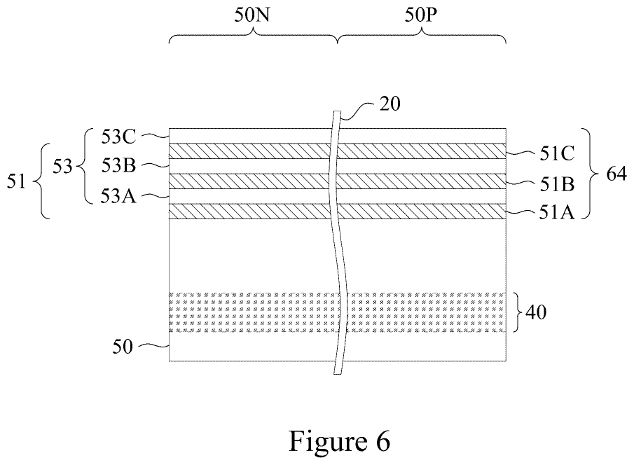

In some embodiments, the etch stop region 40 may have a height D₁ (e.g., a vertical span) that is in the range of about 100 nm to about 300 nm, though other heights are possible. In some cases, the height D₁ of the etch stop region 40 may be defined as a height of the region of the substrate 50 in which the implanted impurity concentration is greater than about 5×10¹⁸ cm⁻³. Other definitions of the height D₁ (e.g., other concentrations) are possible. In some embodiments, the etch stop region 40 may be a distance D₂ from a top surface of the substrate 50 that is in the range of about 40 nm to about 60 nm. In some embodiments, the etch stop region 40 may be a distance D₂ from a multi-layer stack 64 (see FIG. 6) that is in the range of about 40 nm to about 60 nm. Other distances D₂ are possible.

In other embodiments, the etch stop region 40 may comprise an oxide-like material and/or a nitride-like material. In such embodiments, the etch stop region 40 may be formed by implanting oxygen ions and/or nitride ions into the substrate 50. In this manner, the etch stop region 40 may comprise a silicon oxide, a silicon nitride, a silicon oxynitride, or the like. Other materials are possible.

In FIG. 6, a multi-layer stack 64 is formed over the substrate 50, in accordance with some embodiments. The multi-layer stack 64 includes alternating layers of first semiconductor layers 51A-C (collectively referred to as first semiconductor layers 51) and second semiconductor layers 53A-C (collectively referred to as second semiconductor layers 53). For purposes of illustration and as discussed in greater detail below, the second semiconductor layers 53 will be removed and the first semiconductor layers 51 will be patterned to form channel regions of nano-FETs in the n-type region 50N and the p-type region 50P. In such embodiments, the channel regions in both the n-type region 50N and the p-type region 50P may have a same material composition (e.g., silicon, or the another semiconductor material) and may be formed simultaneously.

In some embodiments, the second semiconductor layers 53 may be removed and the first semiconductor layers 51 may be patterned to form channel regions of nano-FETs in the n-type region 50N, and the first semiconductor layers 51 may be removed and the second semiconductor layers 53 may be patterned to form channel regions of nano-FETs in the p-type region 50P. In some embodiments, the first semiconductor layers 51 may be removed and the second semiconductor layers 53 may be patterned to form channel regions of nano-FETs in the n-type region 50N, and the second semiconductor layers 53 may be removed and the first semiconductor layers 51 may be patterned to form channel regions of nano-FETs in the p-type region 50P. In some embodiments, the first semiconductor layers 51 may be removed and the second semiconductor layers 53 may be patterned to form channel regions of nano-FETs in both the n-type region 50N and the p-type region 50P.

The multi-layer stack 64 is illustrated as including three layers of the first semiconductor layers 51 and three layers of the second semiconductor layers 53 for illustrative purposes. In some embodiments, the multi-layer stack 64 may include any number of the first semiconductor layers 51 and the second semiconductor layers 53. Each of the layers of the multi-layer stack 64 may be epitaxially grown using a process such as chemical vapor deposition (CVD), atomic layer deposition (ALD), vapor phase epitaxy (VPE), molecular beam epitaxy (MBE), or the like. In some embodiments, the first semiconductor layers 51 may be formed of a first semiconductor material suitable for p-type nano-FETs, such as silicon germanium or the like. The second semiconductor layers 53 may be formed of a second semiconductor material suitable for n-type nano-FETs, such as silicon, silicon carbide, or the like. The multi-layer stack 64 is illustrated as having a bottommost first semiconductor layer 51 formed of the first semiconductor material for illustrative purposes. In some embodiments, the multi-layer stack 64 may be formed having a bottommost second semiconductor layer 53 formed of the second semiconductor material.

The first semiconductor material and the second semiconductor material may be materials having a high etch selectivity to one another. As such, the first semiconductor layers 51 of the first semiconductor material may be removed without significantly removing the second semiconductor layers 53 of the second semiconductor material. This allows the second semiconductor layers 53 to be patterned to form channel regions of nano-FETs. Similarly, in embodiments in which the second semiconductor layers 53 are removed and the first semiconductor layers 51 are patterned to form channel regions, the second semiconductor layers 53 of the second semiconductor material may be removed without significantly removing the first semiconductor layers 51 of the first semiconductor material. This allows the first semiconductor layers 51 to be patterned to form channel regions of nano-FETs.

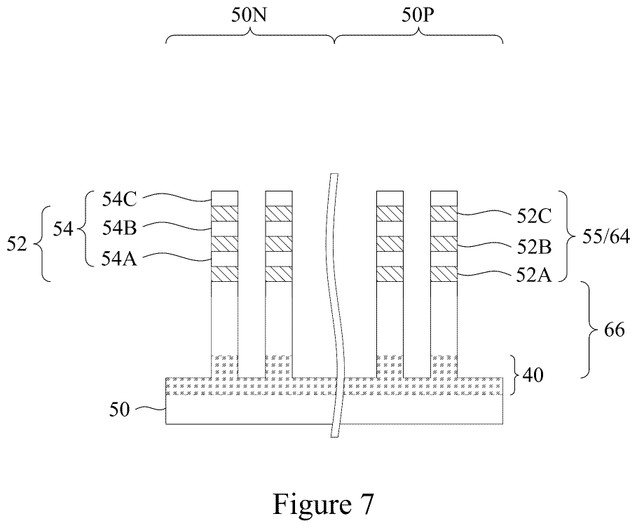

In FIG. 7, fins 66 are formed in the substrate 50 and nanostructures 55 are formed in the multi-layer stack 64. In some embodiments, the nanostructures 55 and the fins 66 may be formed in the multi-layer stack 64 and the substrate 50, respectively, by etching trenches in the multi-layer stack 64 and the substrate 50. The fins 66 may protrude from top surfaces of the substrate 50. In some embodiments, the etching may expose surfaces of the etch stop region 40. In such embodiments, exposed surfaces of the etch stop region 40 may form top surfaces of the substrate 50 and/or sidewall surfaces of the fins 66. In this manner, the fins 66 may comprise portions of the etch stop region 40. In other embodiments, the fins 66 do not include portions of the etch stop region 40. In such embodiments, exposed surfaces of etch stop region 40 may form top surfaces of the substrate 50, or the etch stop region 40 may remain covered by the substrate 50.

The etching may be any acceptable etch process, such as a reactive ion etching (RIE), neutral beam etching (NBE), the like, or a combination thereof. The etching may be anisotropic. Forming the nanostructures 55 by etching the multi-layer stack 64 may further define first nanostructures 52A-C (collectively referred to as first nanostructures 52) from the first semiconductor layers 51 and define second nanostructures 54A-C (collectively referred to as second nanostructures 54) from the second semiconductor layers 53. The first nanostructures 52 and the second nanostructures 54 may be collectively referred to as the nanostructures 55.

The fins 66 and the nanostructures 55 may be patterned by any suitable method. For example, the fins 66 and the nanostructures 55 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins 66 and the nanostructures 55.

FIG. 7 illustrates the fins 66 and the nanostructures 55 in the n-type region 50N and the p-type region 50P as having substantially equal widths for illustrative purposes. In some embodiments, widths of the fins 66 and the nanostructures 55 in the n-type region 50N may be greater than or less than widths of the fins 66 and the nanostructures 55 in the p-type region 50P. Further, while each of the fins 66 and the nanostructures 55 are illustrated as having consistent widths throughout, in some embodiments, the fins 66 and/or the nanostructures 55 may have different sidewalls, such as tapered sidewalls. As such, a width of each of the fins 66 and/or the nanostructures 55 may continuously increase in a direction towards the substrate 50. In such embodiments, each of the nanostructures 55 in a vertical stack may have a different width and may be trapezoidal in shape.

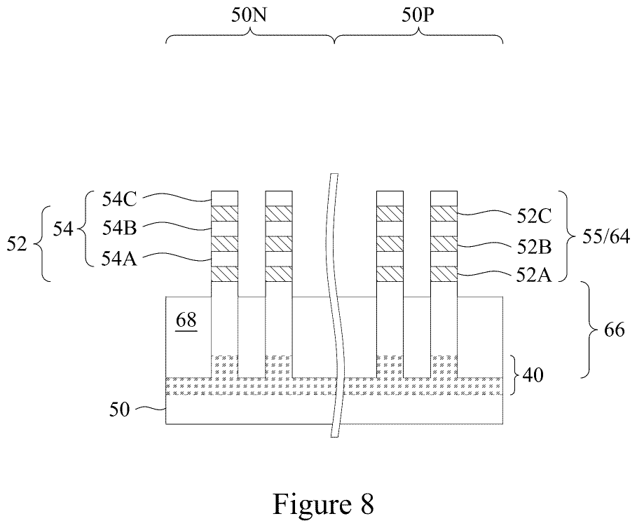

In FIG. 8, shallow trench isolation (STI) regions 68 are formed adjacent the fins 66. The STI regions 68 may be formed by depositing an insulation material over the substrate 50, the fins 66, and the nanostructures 55, and between adjacent ones of the fins 66 and the nanostructures 55. The insulation material may be an oxide (such as silicon oxide), a nitride, the like, or a combination thereof, and may be formed by high-density plasma CVD (HDP-CVD), flowable CVD (FCVD), the like, or a combination thereof. Other insulation materials formed by any acceptable process may be used. In the illustrated embodiment, the insulation material is silicon oxide formed by an FCVD process. An anneal process may be performed once the insulation material is formed. In some embodiments, the insulation material is formed such that excess insulation material covers the nanostructures 55. Although the insulation material is illustrated as a single layer, some embodiments may utilize multiple layers. For example, in some embodiments a liner (not separately illustrated) may be formed along surfaces of the substrate 50, the fins 66, and the nanostructures 55. Thereafter, a fill material, such as those discussed above, may be formed over the liner.

A removal process is then applied to the insulation material to remove excess insulation material over the nanostructures 55. In some embodiments, a planarization process such as a chemical mechanical polish (CMP), an etch-back process, combinations thereof, or the like may be utilized. The planarization process exposes the nanostructures 55, such that top surfaces of the nanostructures 55 and the insulation material are level after the planarization process is complete.

The insulation material is then recessed to form the STI regions 68. The insulation material is recessed such that the nanostructures 55 and the fins 66 in the n-type region 50N and the p-type region 50P protrude from between neighboring ones of the STI regions 68. Top surfaces of the STI regions 68 may have flat surfaces as illustrated, convex surfaces, concave surfaces (such as dishing), or a combination thereof. The top surfaces of the STI regions 68 may be formed flat, convex, and/or concave by an appropriate etch. The STI regions 68 may be recessed using an acceptable etching process, such as one that is selective to the material of the insulation material (e.g., etches the material of the insulation material at a faster rate than the material of the nanostructures 55). As illustrated in FIG. 8, top surfaces of the STI regions 68 may be above top surfaces of the fins 66. However, in some embodiments, the top surfaces of the STI regions 68 may be disposed level with or below the top surfaces of the fins 66. In some embodiments, an oxide removal using dilute hydrofluoric (dHF) acid may be used to etch back the insulation material.

The process described above with respect to FIGS. 6 through 8 is just one example of how the fins 66 and the nanostructures 55 may be formed. In some embodiments, the fins 66 and/or the nanostructures 55 may be formed using a mask and an epitaxial growth process. For example, a dielectric layer may be formed over a top surface of the substrate 50, and trenches may be etched through the dielectric layer to expose the underlying substrate 50. Epitaxial structures may be epitaxially grown in the trenches, and the dielectric layer may be recessed such that the epitaxial structures protrude from the dielectric layer to form the fins 66 and/or the nanostructures 55. The epitaxial structures may comprise alternating layers of the semiconductor materials discussed above, such as the first semiconductor material and the second semiconductor material. In some embodiments in which epitaxial structures are epitaxially grown, the epitaxially grown materials may be in situ doped during growth, which may obviate prior and/or subsequent implantations. In some embodiments, in situ and implantation doping may be used together.

Additionally, the first semiconductor layers 51 (and resulting first nanostructures 52) and the second semiconductor layers 53 (and resulting second nanostructures 54) are illustrated and discussed herein as comprising the same materials in the p-type region 50P and the n-type region 50N for illustrative purposes only. As such, in some embodiments one or both of the first semiconductor layers 51 and the second semiconductor layers 53 may be different materials or formed in a different order in the p-type region 50P and the n-type region 50N.

Further in FIG. 8, appropriate wells (not separately illustrated) may be formed in the fins 66, the nanostructures 55, and/or the STI regions 68. In embodiments with different well types, different implant steps for the n-type region 50N and the p-type region 50P may be achieved using a photoresist or other masks (not separately illustrated). For example, a photoresist may be formed over the fins 66 and the STI regions 68 in the n-type region 50N and the p-type region 50P. The photoresist is patterned to expose the p-type region 50P. The photoresist may be formed by using a spin-on technique and may be patterned using acceptable photolithography techniques. Once the photoresist is patterned, an n-type impurity implant is performed in the p-type region 50P, and the photoresist may act as a mask to prevent n-type impurities from being implanted into the n-type region 50N. The n-type impurities may be phosphorus, arsenic, antimony, or the like implanted in the region to a concentration in a range from about 10¹³ atoms/cm³ to about 10¹⁴ atoms/cm³. After the implant, the photoresist is removed, such as by an acceptable ashing process.

Following or prior to the implanting of the p-type region 50P, a photoresist or other masks (not separately illustrated) is formed over the fins 66, the nanostructures 55, and the STI regions 68 in the p-type region 50P and the n-type region 50N. The photoresist is patterned to expose the n-type region 50N. The photoresist may be formed by using a spin-on technique and may be patterned using acceptable photolithography techniques. Once the photoresist is patterned, a p-type impurity implant may be performed in the n-type region 50N, and the photoresist may act as a mask to prevent p-type impurities from being implanted into the p-type region 50P. The p-type impurities may be boron, boron fluoride, indium, or the like implanted in the region to a concentration in a range from about 1013 atoms/cm3 to about 1014 atoms/cm3. After the implant, the photoresist may be removed, such as by an acceptable ashing process.

After the implants of the n-type region 50N and the p-type region 50P, an anneal may be performed to repair implant damage and to activate the p-type and/or n-type impurities that were implanted. The anneal may be combined with or separate from any of the previously described annealing processes. In some embodiments, the grown materials of epitaxial fins may be in situ doped during growth, which may obviate the implantations. In some embodiments, in situ and implantation doping may be used together.

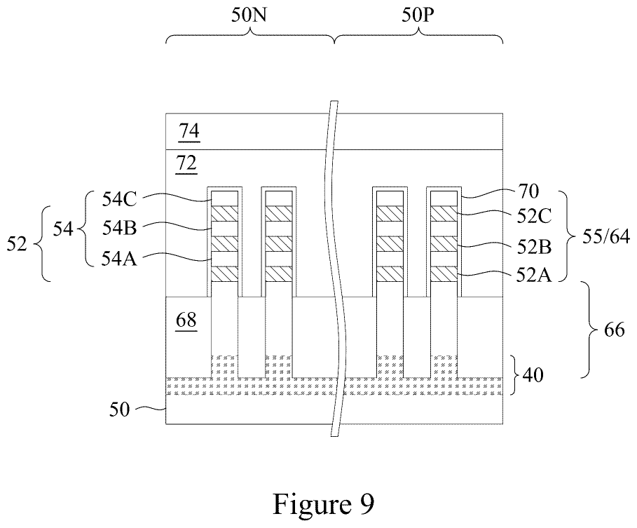

In FIG. 9, a dummy dielectric layer 70 is formed on the fins 66 and/or the nanostructures 55. The dummy dielectric layer 70 may be, for example, silicon oxide, silicon nitride, a combination thereof, or the like. The dummy dielectric layer 70 may be deposited or thermally grown according to acceptable techniques.

A dummy gate layer 72 is formed over the dummy dielectric layer 70, and a mask layer 74 is formed over the dummy gate layer 72. The dummy gate layer 72 may be deposited over the dummy dielectric layer 70 and then planarized, such as by a CMP. The dummy gate layer 72 may be a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals. The dummy gate layer 72 may be deposited by physical vapor deposition (PVD), CVD, sputter deposition, or other techniques for depositing the selected material. The dummy gate layer 72 may be made of other materials that have a high etch selectivity from the etching of the STI regions 68.

The mask layer 74 may be deposited over the dummy gate layer 72. The mask layer 74 may include, for example, silicon nitride, silicon oxynitride, or the like. In the illustrated embodiment, a single dummy gate layer 72 and a single mask layer 74 are formed across the n-type region 50N and the p-type region 50P. It is noted that the dummy dielectric layer 70 is shown covering only the fins 66 and the nanostructures 55 for illustrative purposes only. In some embodiments, the dummy dielectric layer 70 may be deposited such that the dummy dielectric layer 70 covers the STI regions 68. As such, the dummy dielectric layer 70 may extend between the dummy gate layer 72 and the STI regions 68.

FIGS. 10A through 30C illustrate various additional steps in the manufacturing of embodiment devices. FIGS. 10A through 30C illustrate features in either the n-type region 50N or the p-type region 50P. In FIGS. 10A through 10C, the mask layer 74 (see FIG. 9) may be patterned using acceptable photolithography and etching techniques to form masks 78. The pattern of the masks 78 may be transferred to the dummy gate layer 72 and to the dummy dielectric layer 70 to form dummy gates 76 and dummy gate dielectrics 71, respectively. The dummy gates 76 cover respective channel regions of the nanostructures 55. The pattern of the masks 78 may be used to physically separate each of the dummy gates 76 from adjacent dummy gates 76. The dummy gates 76 may have a lengthwise direction perpendicular to the lengthwise direction of respective fins 66 and nanostructures 55.

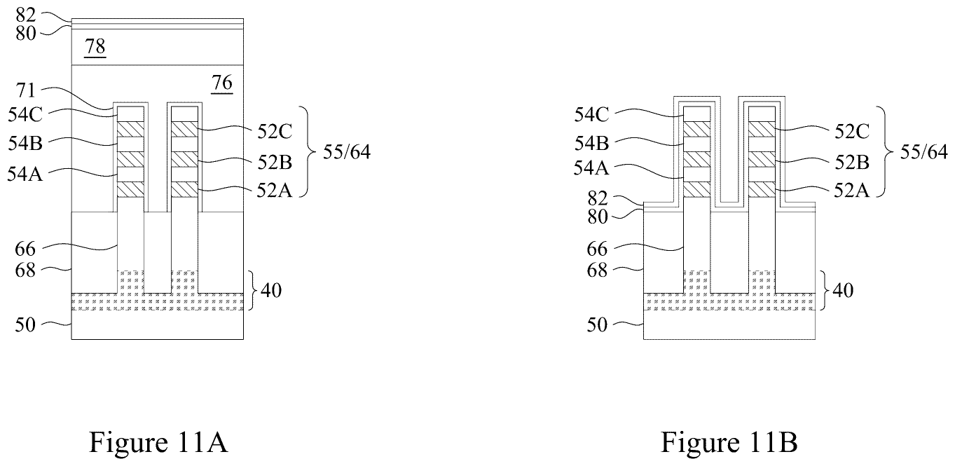

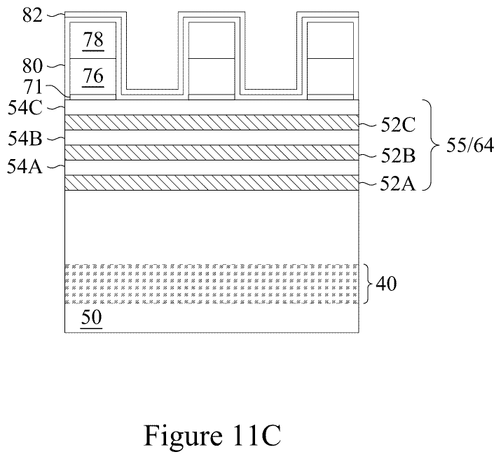

In FIGS. 11A through 11C, a first spacer layer 80 and a second spacer layer 82 are formed over the structures illustrated in FIGS. 10A through 10C, respectively. The first spacer layer 80 and the second spacer layer 82 will be subsequently patterned to act as spacers for forming self-aligned source/drain regions. In FIGS. 11A through 11C, the first spacer layer 80 is formed on top surfaces of the STI regions 68; top surfaces and sidewalls of the nanostructures 55 and the masks 78; and sidewalls of the dummy gates 76, the dummy gate dielectrics 71, and the fins 66. The second spacer layer 82 is deposited over the first spacer layer 80. The first spacer layer 80 may be formed of silicon oxide, silicon nitride, silicon oxynitride, or the like, using techniques such as thermal oxidation or deposited by CVD, ALD, or the like. The second spacer layer 82 may be formed of a material having a different etch rate than the material of the first spacer layer 80, such as silicon oxide, silicon nitride, silicon oxynitride, or the like, and may be deposited by CVD, ALD, or the like.

After the first spacer layer 80 is formed and prior to forming the second spacer layer 82, implants for lightly doped source/drain (LDD) regions (not separately illustrated) may be performed. In embodiments with different device types, similar to the implants discussed above in FIG. 8, a mask, such as a photoresist, may be formed over the n-type region 50N, while exposing the p-type region 50P, and appropriate type (e.g., p-type) impurities may be implanted into the exposed fins 66 and the nanostructures 55 in the p-type region 50P. The mask may then be removed. Subsequently, a mask, such as a photoresist, may be formed over the p-type region 50P while exposing the n-type region 50N, and appropriate type impurities (e.g., n-type) may be implanted into the exposed fins 66 and the nanostructures 55 in the n-type region 50N. The mask may then be removed. The n-type impurities may be the any of the n-type impurities previously discussed, and the p-type impurities may be the any of the p-type impurities previously discussed. The lightly doped source/drain regions may have a concentration of impurities in a range from about 1×10¹⁵ atoms/cm³ to about 1×10¹⁹ atoms/cm³. An anneal may be used to repair implant damage and to activate the implanted impurities.

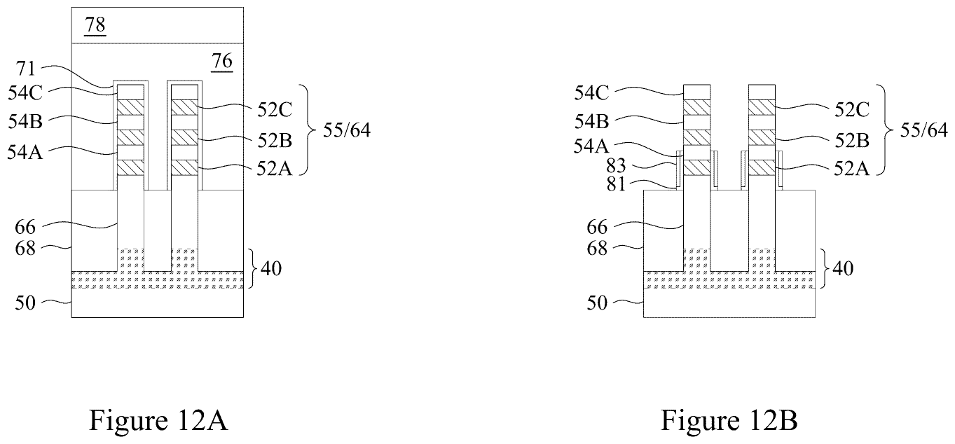

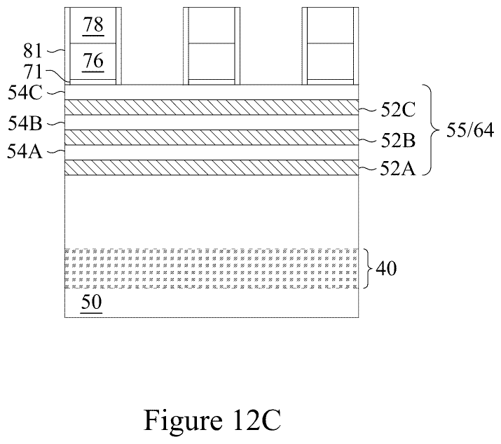

In FIGS. 12A through 12C, the first spacer layer 80 and the second spacer layer 82 are etched to form first spacers 81 and second spacers 83, respectively. As will be discussed in greater detail below, the first spacers 81 and the second spacers 83 act to self-align subsequently formed source/drain regions, as well as to protect sidewalls of the fins 66 and/or the nanostructures 55 during subsequent processing. The first spacer layer 80 and the second spacer layer 82 may be etched using a suitable etching process, such as an isotropic etching process (e.g., a wet etching process), an anisotropic etching process (e.g., a dry etching process), or the like. In some embodiments, the material of the second spacer layer 82 has a different etch rate than the material of the first spacer layer 80, such that the first spacer layer 80 may act as an etch stop layer when patterning the second spacer layer 82 and the second spacer layer 82 may act as a mask when patterning the first spacer layer 80. For example, the second spacer layer 82 may be etched using an anisotropic etch process with the first spacer layer 80 acting as an etch stop layer. Remaining portions of the second spacer layer 82 form the second spacers 83 as illustrated in FIG. 12B. Thereafter, the second spacers 83 act as a mask while etching exposed portions of the first spacer layer 80, forming the first spacers 81, as illustrated in FIGS. 12B and 12C.

As illustrated in FIG. 12B, the first spacers 81 and the second spacers 83 are disposed on sidewalls of the nanostructures 55 and the fins 66. As illustrated in FIG. 12C, in some embodiments, the second spacer layer 82 may be removed from over the first spacer layer 80 adjacent the masks 78, the dummy gates 76, and the dummy gate dielectrics 71, and the first spacers 81 are disposed on sidewalls of the masks 78, the dummy gates 76, and the dummy gate dielectrics 71. In some embodiments, a portion of the second spacer layer 82 may remain over the first spacer layer 80 adjacent the masks 78, the dummy gates 76, and the dummy gate dielectrics 71.

It is noted that the above disclosure generally describes a process of forming spacers and LDD regions. Other processes and sequences may be used. For example, fewer or additional spacers may be utilized, different sequences of steps may be utilized (e.g., the first spacers 81 may be patterned prior to depositing the second spacer layer 82), additional spacers may be formed and removed, and/or the like. Furthermore, the n-type and p-type devices may be formed using different structures and steps.

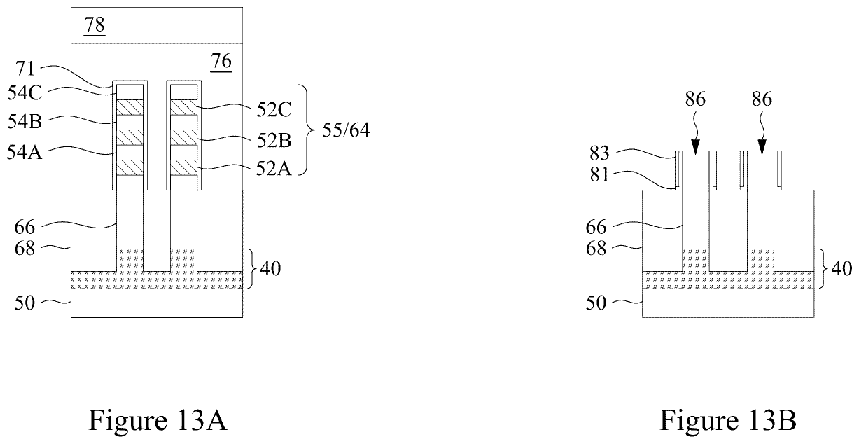

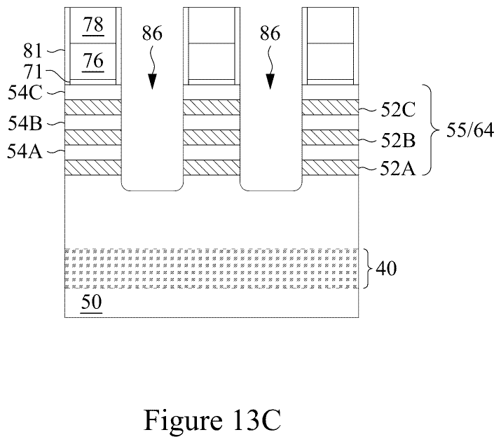

In FIGS. 13A through 13C, recesses 86 are formed in the nanostructures 55, the fins 66, and the substrate 50, in accordance with some embodiments. Epitaxial materials, which may be used as source/drain regions and/or dummy regions, will be subsequently formed in the recesses 86. The recesses 86 may extend through the first nanostructures 52A-52C and the second nanostructures 54A-54C and into the fins 66 and the substrate 50. In some embodiments, top surfaces of the STI regions 68 may be level with bottom surfaces of the recesses 86. In some embodiments, the top surfaces of the STI regions 68 may be above or below the bottom surfaces of the recesses 86.

The recesses 86 may be formed by etching the nanostructures 55, the fins 66, and the substrate 50 using anisotropic etching processes, such as RIE, NBE, or the like. The first spacers 81, the second spacers 83, and the masks 78 mask portions of the nanostructures 55, the fins 66, and the substrate 50 during the etching processes used to form the recesses 86. A single etch process or multiple etch processes may be used to etch each layer of nanostructures 55, the fins 66, and the substrate 50. Timed etch processes may be used to stop the etching after the recesses 86 reach desired depths.

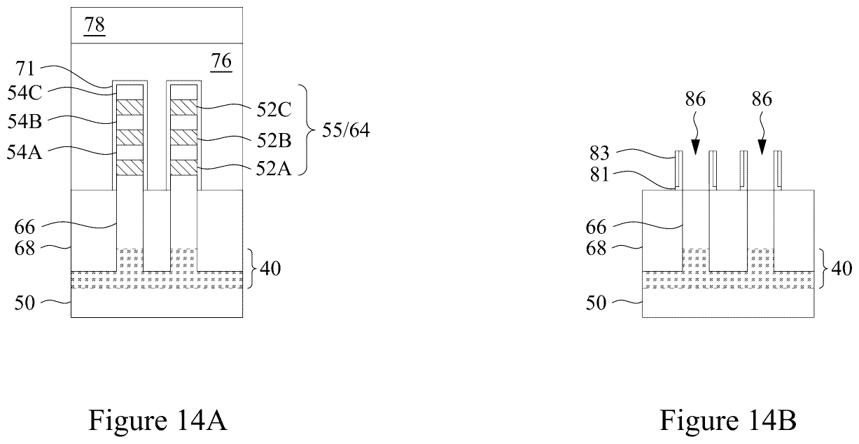

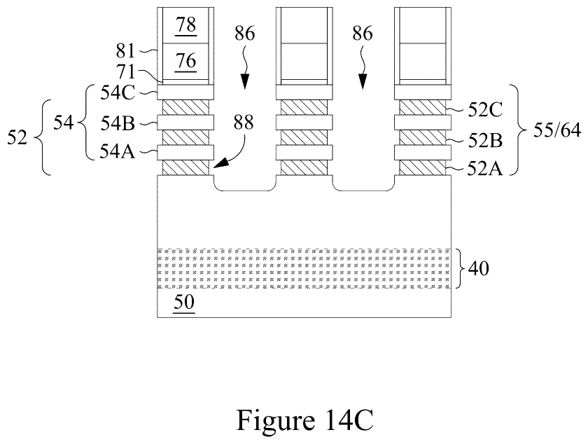

In FIGS. 14A through 14C, portions of sidewalls of the layers of the multi-layer stack 64 formed of the first semiconductor material (e.g., the first nanostructures 52) exposed by the recesses 86 are etched to form sidewall recesses 88 in the n-type region 50N and the p-type region 50P. Although sidewalls of the first nanostructures 52 adjacent the sidewall recesses 88 are illustrated as being straight in FIG. 14C, the sidewalls may be concave or convex. The sidewalls may be etched using isotropic etching processes, such as wet etching or the like. In an embodiment in which the second nanostructures 54 include, e.g., Si or SiC, and the first nanostructures 52 include, e.g., SiGe, a wet or dry etch process with hydrogen fluoride, another fluorine-based etchant, or the like may be used to etch sidewalls of the first nanostructures 52 in the n-type region 50N and the p-type region 50P.

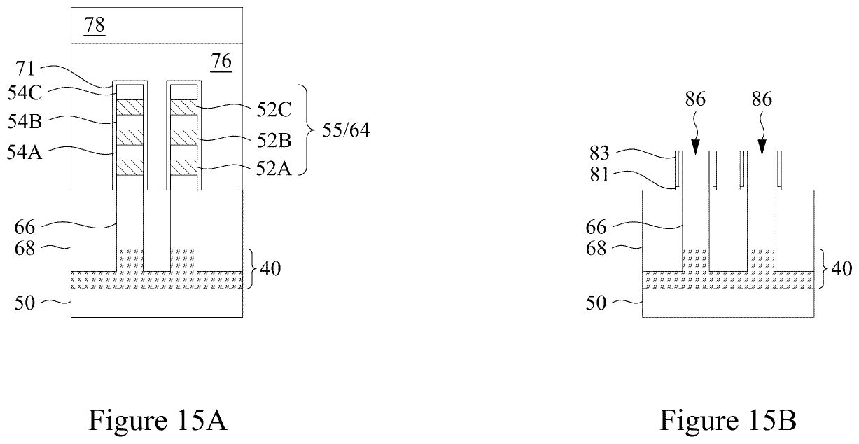

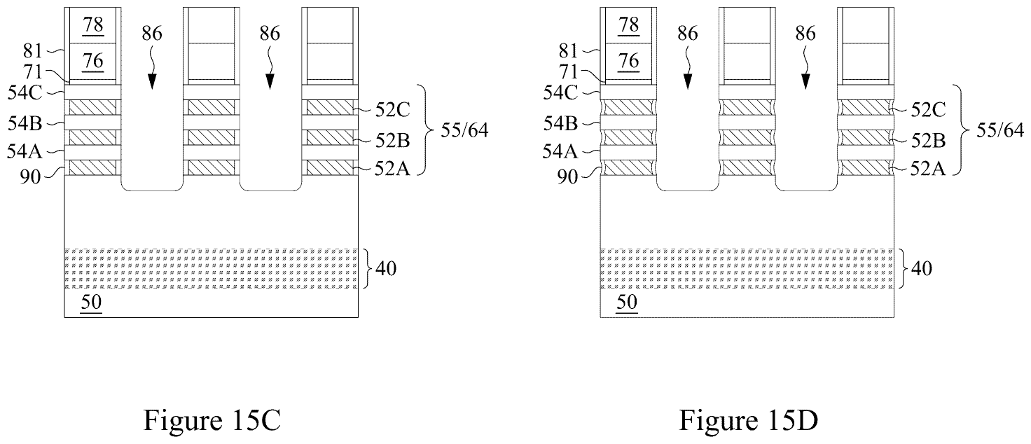

In FIGS. 15A through 15D, first inner spacers 90 are formed in the sidewall recess 88. The first inner spacers 90 may be formed by depositing an inner spacer layer (not separately illustrated) over the structures illustrated in FIGS. 14A through 14C. The first inner spacers 90 act as isolation features between subsequently formed source/drain regions and gate structures. As will be discussed in greater detail below, the source/drain regions will be formed in the recesses 86, while first nanostructures 52 will be replaced with corresponding gate structures.

The inner spacer layer may be deposited by a conformal deposition process, such as CVD, ALD, or the like. The inner spacer layer may comprise a material such as silicon nitride or silicon oxynitride, although any suitable material, such as low-dielectric constant (low-k) materials having a k-value less than about 3.5, may be utilized. The inner spacer layer may then be anisotropically etched to form the first inner spacers 90. Although outer sidewalls of the first inner spacers 90 are illustrated as being flush with sidewalls of the second nanostructures 54, the outer sidewalls of the first inner spacers 90 may extend beyond or be recessed from the sidewalls of the second nanostructures 54.

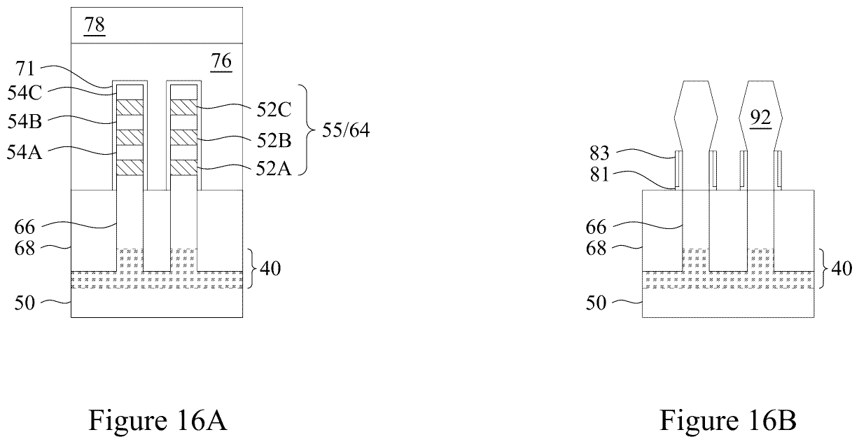

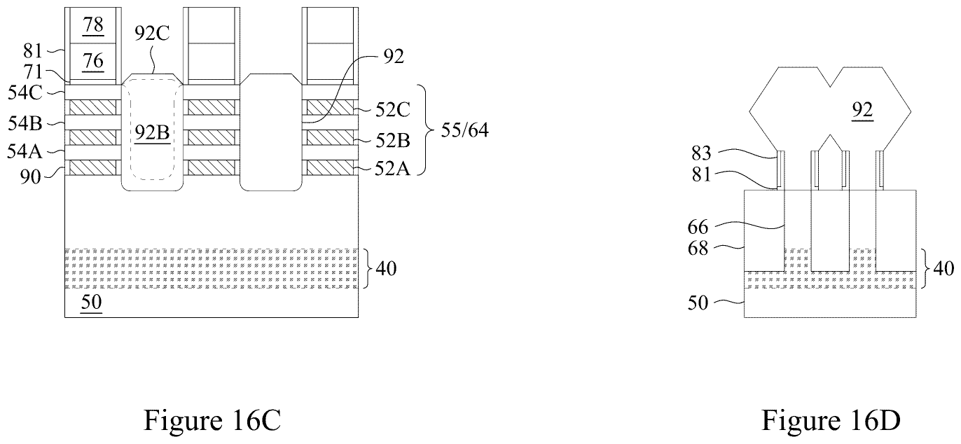

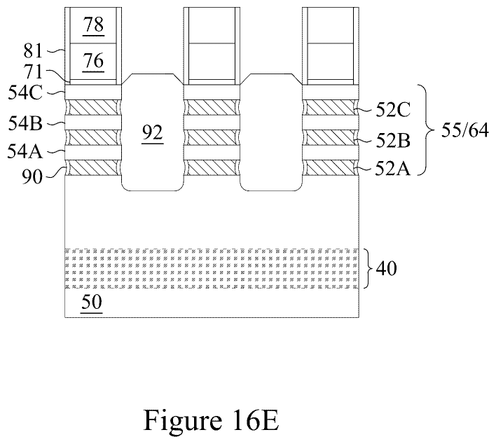

Moreover, although the outer sidewalls of the first inner spacers 90 are illustrated as being straight in FIG. 15C, the outer sidewalls of the first inner spacers 90 may be concave or convex. As an example, FIG. 15D illustrates an embodiment in which sidewalls of the first nanostructures 52 are concave, outer sidewalls of the first inner spacers 90 are concave, and the first inner spacers 90 are recessed from sidewalls of the second nanostructures 54. The inner spacer layer may be etched by an anisotropic etching process, such as RIE, NBE, or the like. The first inner spacers 90 may be used to prevent damage to subsequently formed source/drain regions (such as the epitaxial source/drain regions 92, discussed below with respect to FIGS. 16A through 16E) by subsequent etching processes, such as etching processes used to form gate structures.

In FIGS. 16A through 16E, epitaxial source/drain regions 92 are formed in the recesses 86, in accordance with some embodiments. In some embodiments, the epitaxial source/drain regions 92 may exert stress on the second nanostructures 54, which can improve performance. As illustrated in FIG. 16C, the epitaxial source/drain regions 92 are formed in the recesses 86 such that each dummy gate 76 is disposed between respective neighboring pairs of the epitaxial source/drain regions 92. In some embodiments, the first spacers 81 are used to separate the epitaxial source/drain regions 92 from the dummy gates 76 and the first inner spacers 90 are used to separate the epitaxial source/drain regions 92 from the first nanostructures 52 by an appropriate lateral distance so that the epitaxial source/drain regions 92 do not short out with subsequently formed gates of the resulting nano-FETs.

The epitaxial source/drain regions 92 in the n-type region 50N, e.g., the NMOS region, may be formed by masking the p-type region 50P, e.g., the PMOS region. Then, the epitaxial source/drain regions 92 are epitaxially grown in the recesses 86 in the n-type region 50N. The epitaxial source/drain regions 92 may include any acceptable material appropriate for n-type nano-FETs. For example, if the second nanostructures 54 are silicon, the epitaxial source/drain regions 92 may include materials exerting a tensile strain on the second nanostructures 54, such as silicon, silicon carbide, phosphorous doped silicon carbide, silicon phosphide, or the like. The epitaxial source/drain regions 92 may have surfaces raised from respective upper surfaces of the nanostructures 55 and may have facets.

The epitaxial source/drain regions 92 in the p-type region 50P, e.g., the PMOS region, may be formed by masking the n-type region 50N, e.g., the NMOS region. Then, the epitaxial source/drain regions 92 are epitaxially grown in the recesses 86 in the p-type region 50P. The epitaxial source/drain regions 92 may include any acceptable material appropriate for p-type nano-FETs. For example, if the second nanostructures 54 are silicon, the epitaxial source/drain regions 92 may comprise materials exerting a compressive strain on the second nanostructures 54, such as silicon-germanium, boron doped silicon-germanium, germanium, germanium tin, or the like. The epitaxial source/drain regions 92 may also have surfaces raised from respective surfaces of the nanostructures 55 and may have facets.

The epitaxial source/drain regions 92, the first nanostructures 52, the second nanostructures 54, the fins 66 and/or the substrate 50 may be implanted with dopants to form source/drain regions, similar to the process previously discussed for forming lightly-doped source/drain regions, followed by an anneal. The source/drain regions may have an impurity concentration of between about 1×10¹⁹ atoms/cm³ and about 1×10²¹ atoms/cm³. The n-type and/or p-type impurities for source/drain regions may be any of the impurities previously discussed. In some embodiments, the epitaxial source/drain regions 92 may be in situ doped during growth.

As a result of the epitaxy processes used to form the epitaxial source/drain regions 92 in the n-type region 50N and the p-type region 50P, upper surfaces of the epitaxial source/drain regions 92 have facets which expand laterally outward beyond sidewalls of the nanostructures 55. In some embodiments, these facets cause adjacent epitaxial source/drain regions 92 of a same nano-FET to merge, as illustrated by FIG. 16D. In some embodiments, adjacent epitaxial source/drain regions 92 remain separated after the epitaxy process is completed, as illustrated by FIG. 16B. In the embodiments illustrated in FIGS. 16B and 16D, the first spacers 81 may be formed extending to top surfaces of the STI regions 68, thereby blocking the epitaxial growth. In some embodiments, the spacer etch used to form the first spacers 81 may be adjusted to remove the spacer material and allow the epitaxially grown region to extend to the surface of the STI region 68.

The epitaxial source/drain regions 92 may comprise one or more semiconductor material layers. For example, the epitaxial source/drain regions 92 may comprise a first semiconductor material layer 92A, a second semiconductor material layer 92B, and a third semiconductor material layer 92C. Any number of semiconductor material layers may be used for the epitaxial source/drain regions 92. Each of the first semiconductor material layer 92A, the second semiconductor material layer 92B, and the third semiconductor material layer 92C may be formed of different semiconductor materials and may be doped to different dopant concentrations. In some embodiments, the first semiconductor material layer 92A may have a dopant concentration less than the second semiconductor material layer 92B and greater than the third semiconductor material layer 92C. In embodiments in which the epitaxial source/drain regions 92 comprise three semiconductor material layers, the first semiconductor material layer 92A may be deposited, the second semiconductor material layer 92B may be deposited over the first semiconductor material layer 92A, and the third semiconductor material layer 92C may be deposited over the second semiconductor material layer 92B. In other embodiments, sacrificial epitaxial material (not shown) may be formed in one or more recesses 86 before forming the epitaxial source/drain regions 92.

FIG. 16E illustrates an embodiment in which sidewalls of the first nanostructures 52 are concave, outer sidewalls of the first inner spacers 90 are concave, and the first inner spacers 90 are recessed from sidewalls of the second nanostructures 54. As illustrated in FIG. 16E, the epitaxial source/drain regions 92 may be formed in contact with the first inner spacers 90 and may extend past sidewalls of the second nanostructures 54.

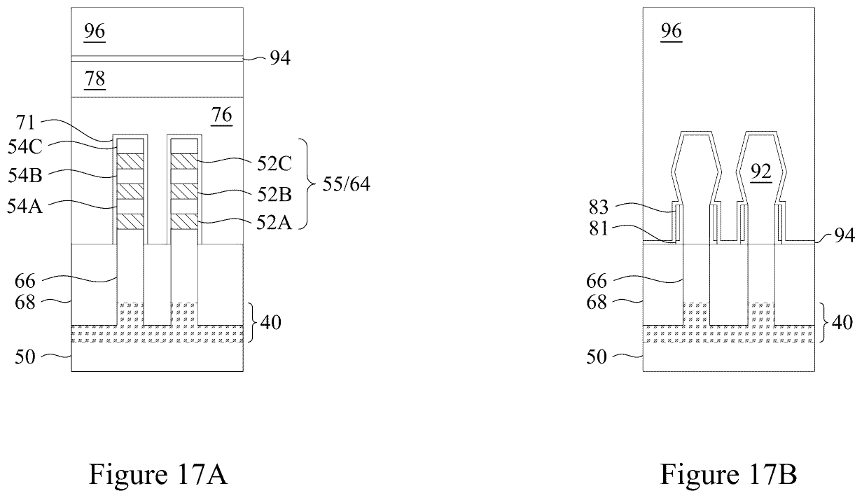

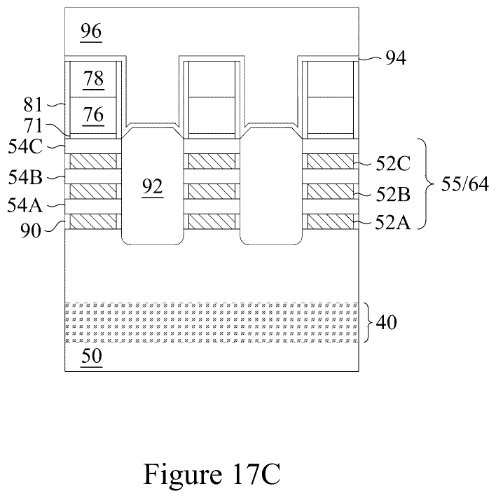

In FIGS. 17A through 17C, a first interlayer dielectric (ILD) 96 is deposited over the structure illustrated in FIGS. 16A through 16C, respectively. The first ILD 96 may be formed of a dielectric material, and may be deposited by any suitable method, such as CVD, plasma-enhanced CVD (PECVD), or FCVD. Dielectric materials may include phosphosilicate glass (PSG), borosilicate glass (BSG), boron-doped phosphosilicate glass (BPSG), undoped silicate glass (USG), or the like. Other insulation materials formed by any acceptable process may be used. In some embodiments, a contact etch stop layer (CESL) 94 is disposed between the first ILD 96 and the epitaxial source/drain regions 92, the masks 78, the first spacers 81, the second spacers 83, and the STI regions 68. The CESL 94 may comprise a dielectric material, such as, silicon nitride, silicon oxide, silicon oxynitride, or the like, having a different etch rate than the material of the overlying first ILD 96.

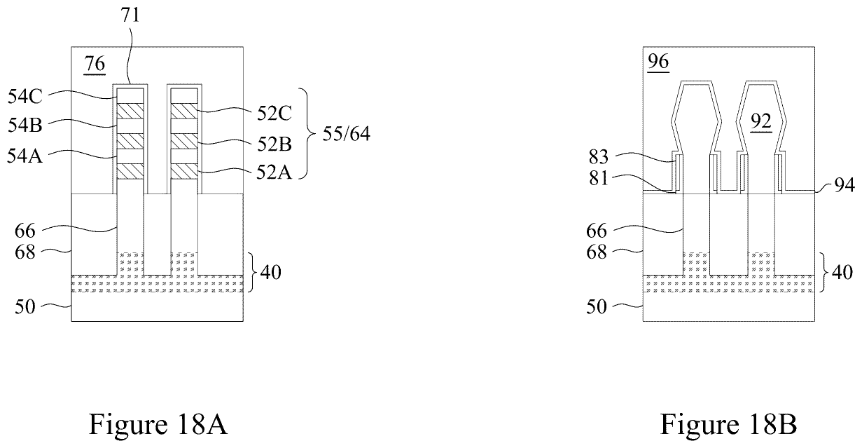

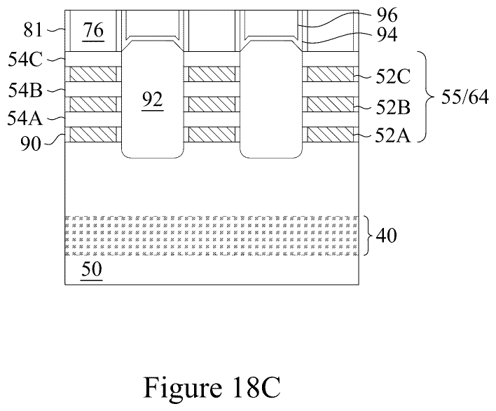

In FIGS. 18A through 18C, a planarization process, such as a CMP, may be performed to level the top surfaces of the first ILD 96 and the CESL 94 with the top surfaces of the dummy gates 76 or the masks 78. The planarization process may also remove the masks 78 on the dummy gates 76, and portions of the first spacers 81 along sidewalls of the masks 78. After the planarization process, top surfaces of the dummy gates 76, the first spacers 81, the first ILD 96, and the CESL 94 may be level with one another, within process variations. Accordingly, the top surfaces of the dummy gates 76 are exposed through the first ILD 96. In some embodiments, the masks 78 may remain, in which case the planarization process levels top surfaces of the first ILD 96 with top surfaces of the masks 78, the first spacers 81, and the CESL 94.

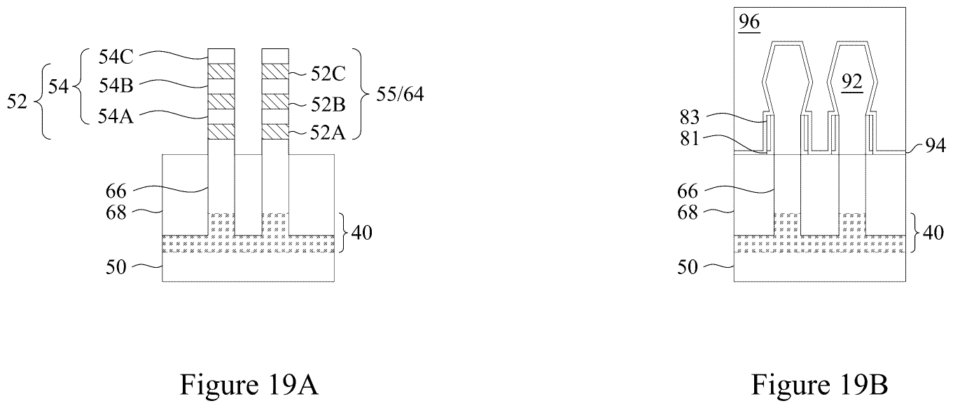

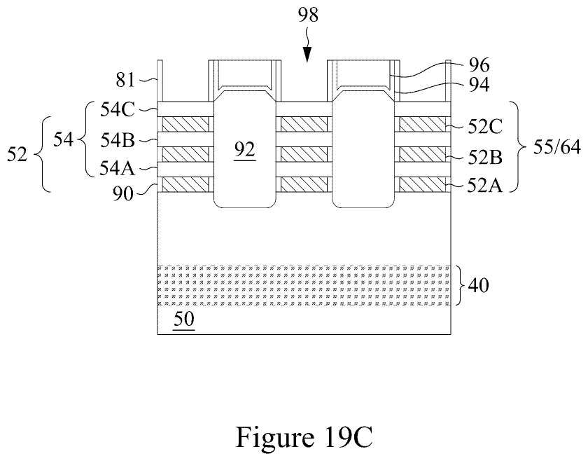

In FIGS. 19A through 19C, the dummy gates 76, and the masks 78 if present, are removed in one or more etching steps, forming recesses 98. Portions of the dummy gate dielectrics 71 in the recesses 98 are also be removed. In some embodiments, the dummy gates 76 and the dummy gate dielectrics 71 are removed by an anisotropic dry etch process. For example, the etching process may include a dry etch process using reaction gas(es) that selectively etch the dummy gates 76 at a faster rate than the first ILD 96, the CESL 94, or the first spacers 81. Each of the recesses 98 exposes and/or overlies portions of nanostructures 55, which act as channel regions in subsequently completed nano-FETs. Portions of the nanostructures 55 which act as the channel regions are disposed between neighboring pairs of the epitaxial source/drain regions 92. During the removal, the dummy gate dielectrics 71 may be used as etch stop layers when the dummy gates 76 are etched. The dummy gate dielectrics 71 may then be removed after the removal of the dummy gates 76.

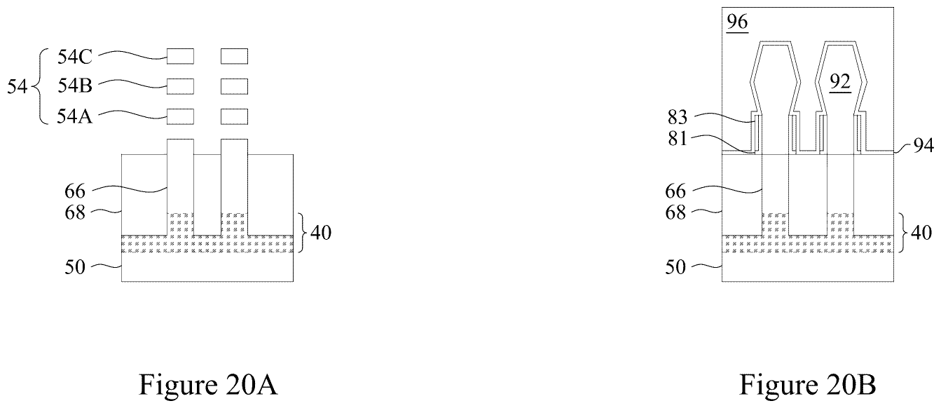

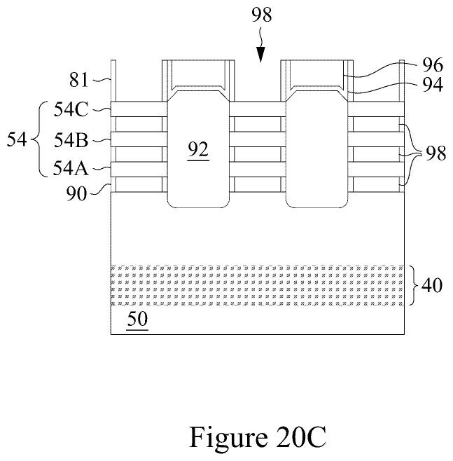

In FIGS. 20A through 20C, the first nanostructures 52 are removed, which extends the recesses 98. The first nanostructures 52 may be removed by performing an isotropic etching process, such as wet etching or the like, using etchants that are selective to the materials of the first nanostructures 52, while the second nanostructures 54, the substrate 50, the STI regions 68, the first ILD 96, the CESL 94, the first spacers 81, and the first inner spacers 90 remain relatively un-etched as compared to the first nanostructures 52. In embodiments in which the second nanostructures 54 include, e.g., Si or SiC, and the first nanostructures 52 include, e.g., SiGe, tetramethylammonium hydroxide (TMAH), ammonium hydroxide (NH₄OH), or the like may be used to remove the first nanostructures 52.

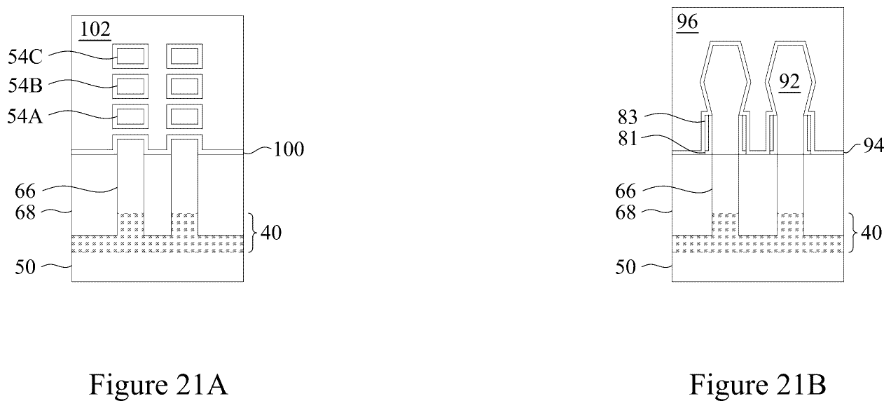

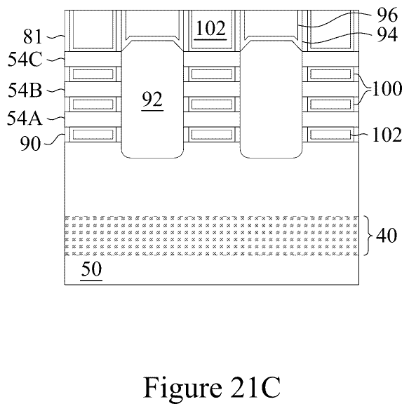

In FIGS. 21A through 21C, gate dielectric layers 100 and gate electrodes 102 are formed for replacement gates. The gate dielectric layers 100 are deposited conformally in the recesses 98. The gate dielectric layers 100 may be formed on top surfaces, sidewalls, and bottom surfaces of the second nanostructures 54. The gate dielectric layers 100 may also be deposited on top surfaces of the first ILD 96, the CESL 94, the first spacers 81, and the STI regions 68.

In accordance with some embodiments, the gate dielectric layers 100 comprise one or more dielectric layers, such as an oxide, a metal oxide, the like, or combinations thereof. For example, in some embodiments, the gate dielectric layers 100 may comprise a silicon oxide layer and a metal oxide layer over the silicon oxide layer. In some embodiments, the gate dielectric layers 100 include a high-k dielectric material, and in these embodiments, the gate dielectric layers 100 may have a k-value greater than about 7.0, and may include a metal oxide or a silicate of hafnium, aluminum, zirconium, lanthanum, manganese, barium, titanium, lead, and combinations thereof. The structure of the gate dielectric layers 100 may be the same or different in the n-type region 50N and the p-type region 50P. The formation methods of the gate dielectric layers 100 may include molecular-beam deposition (MBD), ALD, PECVD, or the like.

The gate electrodes 102 are deposited over the gate dielectric layers 100 and fill remaining portions of the recesses 98. The gate electrodes 102 may include a metal-containing material such as titanium nitride, titanium oxide, tantalum nitride, tantalum carbide, cobalt, ruthenium, aluminum, tungsten, combinations thereof, or multi-layers thereof. For example, although single-layer gate electrodes 102 are illustrated in FIGS. 21A and 21C, the gate electrodes 102 may comprise any number of liner layers, any number of work function tuning layers, and a fill material. Any combination of the layers that make up the gate electrodes 102 may be deposited between adjacent ones of the second nanostructures 54.

The formation of the gate dielectric layers 100 in the n-type region 50N and the p-type region 50P may occur simultaneously such that the gate dielectric layers 100 in each region are formed from the same materials, and the formation of the gate electrodes 102 may occur simultaneously such that the gate electrodes 102 in each region are formed from the same materials. In some embodiments, the gate dielectric layers 100 in each region may be formed by distinct processes, such that the gate dielectric layers 100 may be different materials and/or have a different number of layers, and/or the gate electrodes 102 in each region may be formed by distinct processes, such that the gate electrodes 102 may be different materials and/or have a different number of layers. Various masking steps may be used to mask and expose appropriate regions when using distinct processes.

After the filling of the recesses 98, a planarization process, such as a CMP, may be performed to remove the excess portions of the gate dielectric layers 100 and the material of the gate electrodes 102, which excess portions are over the top surfaces of the first ILD 96, the first spacers 81, and the CESL 94. The remaining portions of material of the gate electrodes 102 and the gate dielectric layers 100 thus form replacement gate structures of the resulting nano-FETs. The gate electrodes 102 and the gate dielectric layers 100 may be collectively referred to as “gate structures.”

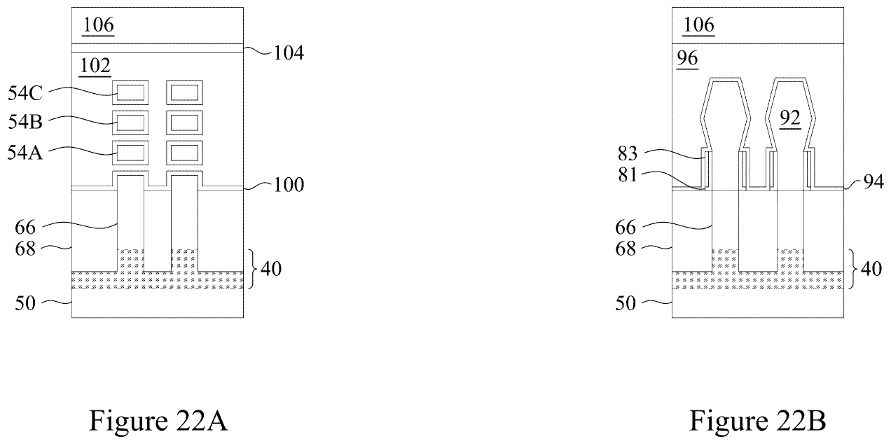

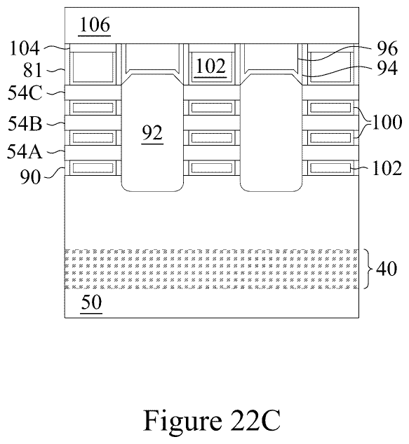

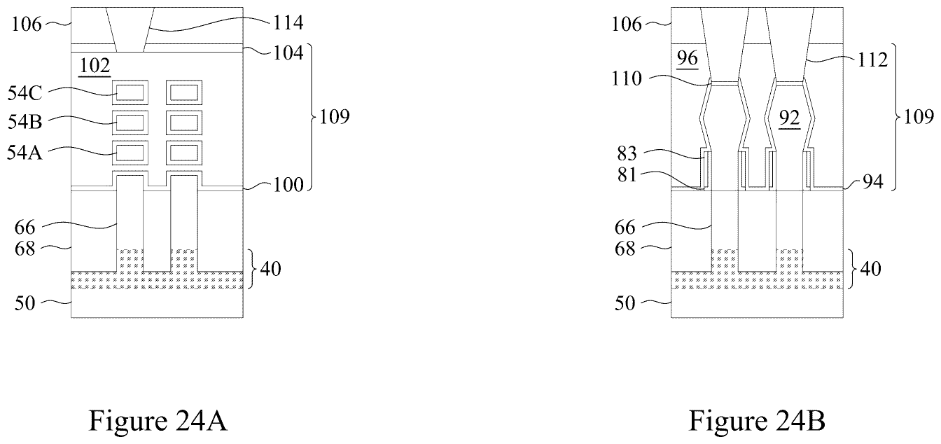

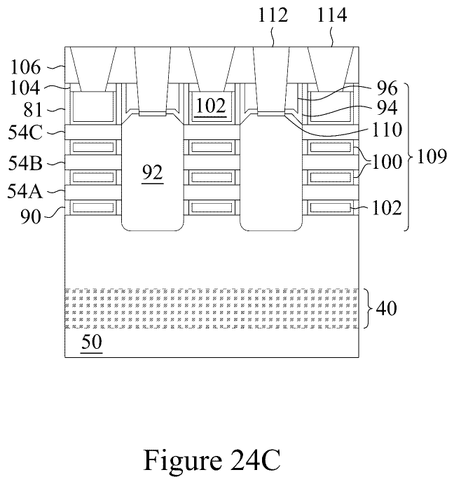

In FIGS. 22A through 22C, the gate structures (including the gate dielectric layers 100 and the corresponding overlying gate electrodes 102) are recessed, so that recesses are formed directly over each of the gate structures and between opposing portions of the first spacers 81. Gate masks 104 comprising one or more layers of dielectric material, such as silicon nitride, silicon oxynitride, or the like, are filled in the recesses, followed by a planarization process to remove excess portions of the dielectric material extending over the first ILD 96, the CESL 94, and the first spacers 81. Subsequently formed gate contacts (such as the gate contacts 114, discussed below with respect to FIGS. 24A and 24C) penetrate through the gate masks 104 to contact the top surface of the recessed gate electrodes 102.

As further illustrated by FIGS. 22A through 22C, a second ILD 106 is deposited over the first ILD 96, the CESL 94, and the gate masks 104. In some embodiments, the second ILD 106 is a flowable film formed by FCVD. In some embodiments, the second ILD 106 is formed of a dielectric material such as PSG, BSG, BPSG, USG, or the like, and may be deposited by any suitable method, such as CVD, PECVD, or the like.

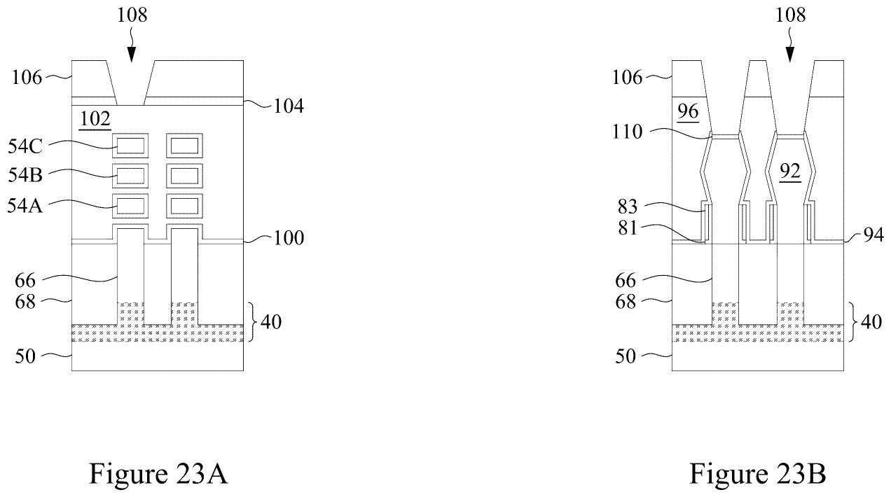

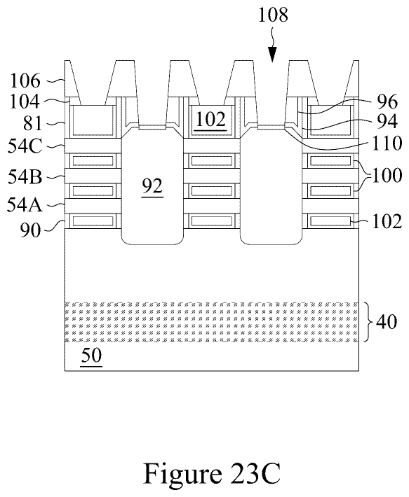

In FIGS. 23A through 23C, the second ILD 106, the first ILD 96, the CESL 94, and the gate masks 104 are etched to form recesses 108 exposing surfaces of the epitaxial source/drain regions 92 and/or the gate structures. The recesses 108 may be formed by etching using an anisotropic etching process, such as RIE, NBE, or the like. In some embodiments, the recesses 108 may be etched through the second ILD 106 and the first ILD 96 using a first etching process; may be etched through the gate masks 104 using a second etching process; and may be etched through the CESL 94 using a third etching process. A mask, such as a photoresist, may be formed and patterned over the second ILD 106 to mask portions of the second ILD 106 from the first etching process and the second etching process. In some embodiments, the etching process may over-etch, and therefore, the recesses 108 may extend into the epitaxial source/drain regions 92 and/or the gate structures. Bottom surfaces of the recesses 108 may be level with (e.g., at a same level, or having a same distance from the substrate 50), or lower than (e.g., closer to the substrate 50) top surfaces of the epitaxial source/drain regions 92 and/or the gate structures. Although FIG. 23C illustrates the recesses 108 as exposing the epitaxial source/drain regions 92 and the gate structures in a same cross-section, in some embodiments, the epitaxial source/drain regions 92 and the gate structures may be exposed in different cross-sections, thereby reducing the risk of shorting subsequently formed contacts.

After the recesses 108 are formed, first silicide regions 110 are formed over the epitaxial source/drain regions 92. In some embodiments, the first silicide regions 110 are formed by first depositing a metal (not separately illustrated) capable of reacting with the semiconductor materials of the underlying epitaxial source/drain regions 92 (e.g., silicon, silicon germanium, germanium, or the like) to form silicide or germanide regions. The metal may include nickel, cobalt, titanium, tantalum, platinum, tungsten, other noble metals, other refractory metals, rare earth metals or their alloys. The metal may be deposited over the exposed portions of the epitaxial source/drain regions 92, then a thermal anneal process may be performed to form the first silicide regions 110. The unreacted portions of the deposited metal are then removed by, e.g., an etching process. Although the first silicide regions 110 are referred to as silicide regions, the first silicide regions 110 may also be germanide regions, or silicon germanide regions (e.g., regions comprising silicon and germanium), or the like. In an embodiment, the first silicide regions 110 comprise TiSi, and have thicknesses ranging from about 2 nm to about 10 nm.

In FIGS. 24A through 24C, source/drain contacts 112 and gate contacts 114 (also referred to as contact plugs) are formed in the recesses 108. The source/drain contacts 112 and the gate contacts 114 may each comprise one or more layers, such as barrier layers, diffusion layers, and conductive fill materials. For example, in some embodiments, the source/drain contacts 112 and the gate contacts 114 each include a barrier layer and a conductive fill material. The source/drain contacts 112 and the gate contacts 114 are each electrically coupled to the underlying conductive feature (e.g., the gate electrodes 102 or the first silicide regions 110 over the epitaxial source/drain regions 92 in the illustrated embodiment). The gate contacts 114 are electrically coupled to the gate electrodes 102, and the source/drain contacts 112 are electrically coupled to the first silicide regions 110 over the epitaxial source/drain regions 92. The barrier layer may include titanium, titanium nitride, tantalum, tantalum nitride, or the like. The conductive fill material may be copper, a copper alloy, silver, gold, tungsten, cobalt, aluminum, nickel, or the like. A planarization process, such as a CMP, may be performed to remove excess portions of the source/drain contacts 112 and the gate contacts 114, which excess portions are over top surfaces of the second ILD 106.

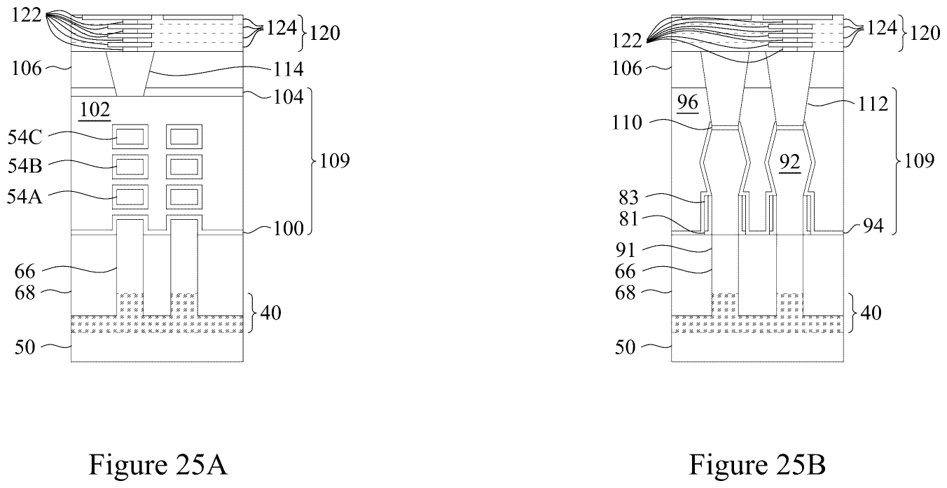

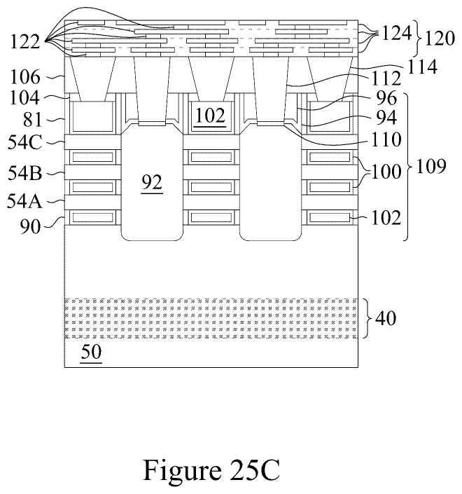

Although FIGS. 20A through 20C illustrate a source/drain contact 112 extending to each of the epitaxial source/drain regions 92, the source/drain contacts 112 may be omitted from certain ones of the epitaxial source/drain regions 92. For example, as explained below, conductive lines (e.g., power rails) may be subsequently attached through a backside of one or more of the epitaxial source/drain regions 92. For these particular epitaxial source/drain regions 92, the source/drain contacts 112 may be omitted or may be dummy contacts that are not electrically coupled to any overlying conductive lines (such as the conductive features 122, discussed below with respect to FIGS. 25A through 25C).

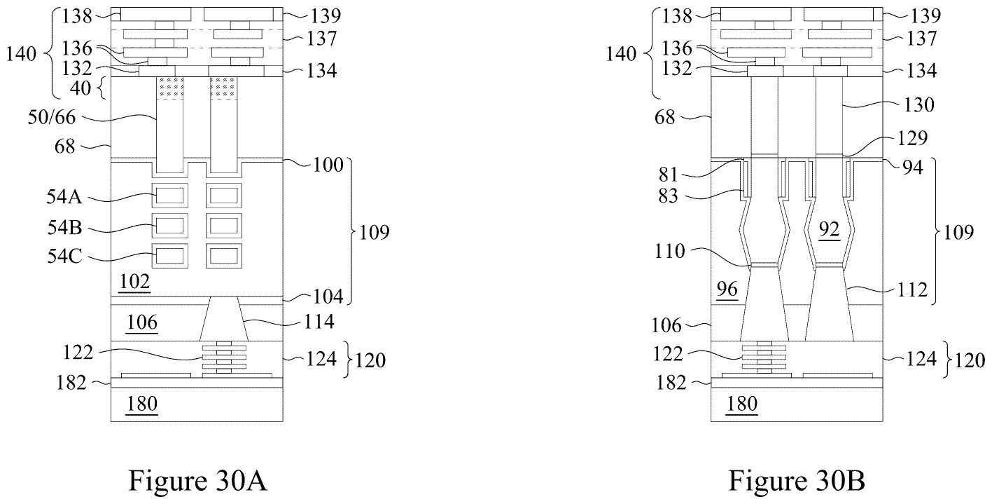

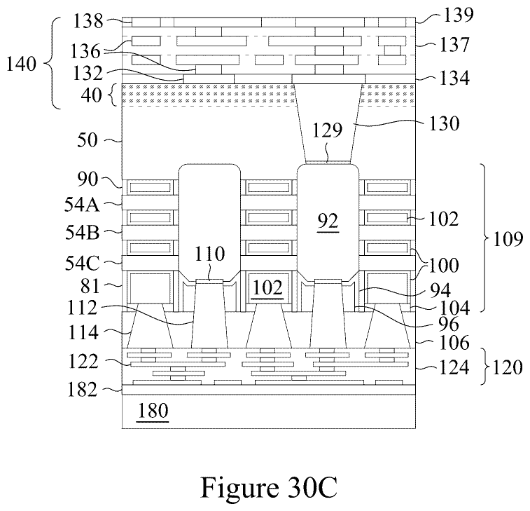

The processes of FIGS. 2 through 24C form a device layer 109 that includes a plurality of active devices. Although the device layer 109 is described as including nanoFETs, other embodiments may include device layers 109 that include different types of transistors, such as planar FETs, FinFETs, thin film transistors (TFTs), or the like. The device layer may include the epitaxial source/drain regions 92, the second nanostructures 54, and the gate structures (including the gate dielectric layers 100 and the gate electrodes 102). A first interconnect structure (such as the front-side interconnect structure 120, discussed below with respect to FIGS. 25A through 25C) may be formed over a front-side of the device layer 109 and a second interconnect structure (such as the backside interconnect structure 140, discussed below with respect to FIGS. 30A through 30C) may be formed over a backside of the device layer 109.

FIGS. 25A through 30C illustrate intermediate steps of forming front-side interconnect structures and backside interconnect structures on the device layer 109. The front-side interconnect structures and the backside interconnect structures may each comprise conductive features that are electrically coupled to devices in the device layer 109 (e.g., the nano-FETs). In FIGS. 25A through 30C, figures ending in “A” illustrate a cross-sectional view along line A-A′ of FIG. 1, figures ending in “B” illustrate a cross-sectional view along line B-B′ of FIG. 1, and figures ending in “C” illustrate a cross-sectional view along line C-C′ of FIG. 1. The process steps described in FIGS. 25A through 30C may be applied to both the n-type region 50N and the p-type region 50P. As noted above, a backside conductive feature (e.g., a backside via or a power rail) may be electrically coupled to one or more of the epitaxial source/drain regions 92. As such, the source/drain contacts 112 may be optionally omitted from the epitaxial source/drain regions 92.

In FIGS. 25A through 25C, a front-side interconnect structure 120 is formed on the second ILD 106. The front-side interconnect structure 120 may be referred to as a front-side interconnect structure because it is formed on a front-side of the device layer 109 (e.g., a side of the device layer 109 opposite the substrate 50 on which active devices are formed). The front-side interconnect structure 120 may comprise one or more layers of conductive features 122 formed in one or more stacked dielectric layers 124. Each of the stacked dielectric layers 124 may comprise a dielectric material, such as a low-k dielectric material, an extra low-k (ELK) dielectric material, or the like. The dielectric layers 124 may be deposited using an appropriate process, such as, CVD, ALD, PVD, PECVD, or the like. The conductive features 122 may comprise conductive lines and conductive vias interconnecting the layers of conductive lines. The conductive vias may extend through respective ones of the dielectric layers 124 to provide vertical connections between layers of the conductive lines. The conductive features 122 may be formed through any acceptable process, such as, a damascene process, a dual damascene process, or the like.

In some embodiments, the conductive features 122 may be formed using a damascene process in which a respective dielectric layer 124 is patterned utilizing a combination of photolithography and etching techniques to form trenches corresponding to the desired pattern of the conductive features 122. An optional diffusion barrier and/or optional adhesion layer may be deposited and the trenches may then be filled with a conductive material. Suitable materials for the barrier layer include titanium, titanium nitride, titanium oxide, tantalum, tantalum nitride, tantalum oxide, combinations thereof, or the like, and suitable materials for the conductive material include copper, silver, gold, tungsten, aluminum, cobalt, tungsten, ruthenium, combinations thereof, or the like. In an embodiment, the conductive features 122 may be formed by depositing a seed layer of copper or a copper alloy, and filling the trenches by electroplating. A CMP process or the like may be used to remove excess conductive material from a surface of the respective dielectric layer 124 and to planarize surfaces of the dielectric layer 124 and the conductive features 122 for subsequent processing.

FIGS. 25A through 25C illustrate four layers of the conductive features 122 and the dielectric layers 124 in the front-side interconnect structure 120. However, it should be appreciated that the front-side interconnect structure 120 may comprise any number of conductive features 122 disposed in any number of dielectric layers 124. The front-side interconnect structure 120 may be electrically coupled to the gate contacts 114 and the source/drain contacts 112 to form functional circuits. In some embodiments, the functional circuits formed by the front-side interconnect structure 120 may comprise logic circuits, memory circuits, image sensor circuits, or the like.

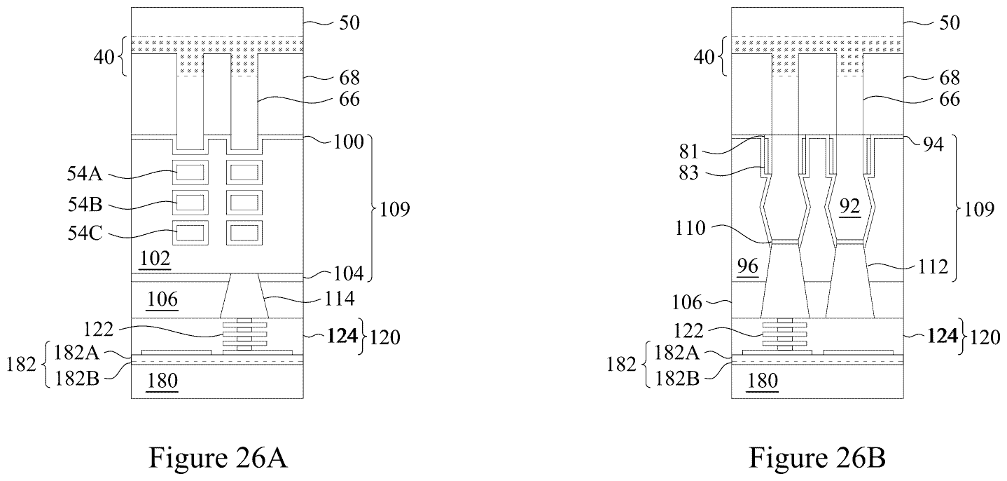

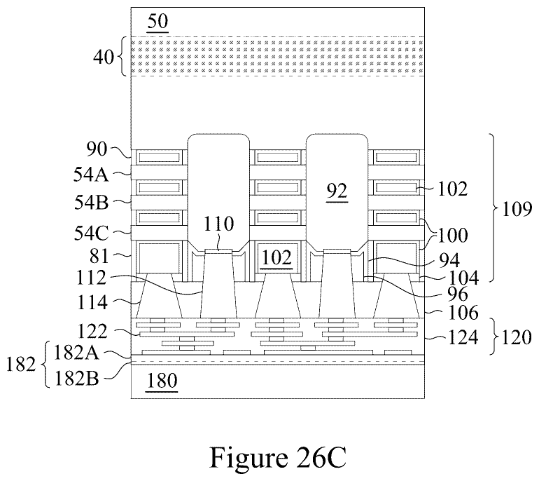

In FIGS. 26A through 26C, a carrier substrate 180 is bonded to a top surface of the front-side interconnect structure 120 by a first bonding layer 182A and a second bonding layer 182B (collectively referred to as bonding layers 182). The carrier substrate 180 may be a glass carrier substrate, a ceramic carrier substrate, a wafer (e.g., a silicon wafer), or the like. The carrier substrate 180 may provide structural support during subsequent processing steps and in the completed device.

In various embodiments, the carrier substrate 180 may be bonded to the front-side interconnect structure 120 using a suitable technique, such as dielectric-to-dielectric bonding, or the like. The dielectric-to-dielectric bonding may comprise depositing the first bonding layer 182A on the front-side interconnect structure 120. In some embodiments, the first bonding layer 182A comprises silicon oxide (e.g., a high-density plasma (HDP) oxide, or the like) that is deposited by CVD, ALD, PVD, or the like. The second bonding layer 182B may likewise be an oxide layer that is formed on a surface of the carrier substrate 180 prior to bonding using, for example, CVD, ALD, PVD, thermal oxidation, or the like. Other suitable materials may be used for the first bonding layer 182A and the second bonding layer 182B.

The dielectric-to-dielectric bonding process may further include applying a surface treatment to one or more of the first bonding layer 182A and the second bonding layer 182B. The surface treatment may include a plasma treatment. The plasma treatment may be performed in a vacuum environment. After the plasma treatment, the surface treatment may further include a cleaning process (e.g., a rinse with deionized water or the like) that may be applied to one or more of the bonding layers 182. The carrier substrate 180 is then aligned with the front-side interconnect structure 120 and the two are pressed against each other to initiate a pre-bonding of the carrier substrate 180 to the front-side interconnect structure 120. The pre-bonding may be performed at room temperature (e.g., between about 21° C. and about 2520 C.). After the pre-bonding, an annealing process may be applied by, for example, heating the front-side interconnect structure 120 and the carrier substrate 180 to a temperature of about 170° C.

Further in FIGS. 26A through 26C, after the carrier substrate 180 is bonded to the front-side interconnect structure 120, the device may be flipped such that a backside of the device layer 109 faces upwards. The backside of the device layer 109 may refer to a side opposite to the front-side of the device layer 109.

In FIGS. 27A through 27C, a thinning process is applied to the backside of the substrate 50, in accordance with some embodiments. The thinning process may comprise a planarization process (e.g., a mechanical grinding, a CMP process, or the like), an etch-back process, a combination thereof, or the like. In some embodiments, the thinning process is slowed or stopped by the etch stop region 40, described in greater detail below. The thinning process may expose surfaces of the substrate 50, the STI regions 68, and/or the fins 66 opposite the front-side interconnect structure 120. The exposed surfaces of the substrate 50 and/or the fins 66 may include exposed surfaces of the etch stop region 40, in some embodiments. Further, a portion of the substrate 50 may remain over the device layer 109 after the thinning process. The remaining portion of the substrate 50 may include a portion of the etch stop region 40, in some embodiments. In other embodiments, the thinning process may remove all of the etch stop region 40. In some embodiments, after performing the thinning process, the remaining portions of the substrate 50 and/or the fins 66 may have a height D₃ that is in the range of about 40 nm to about 60 nm, though other heights are possible.

As illustrated in FIGS. 27A through 27C, backside surfaces of the substrate 50, the STI regions 68, and/or the fins 66 may be level with one another following the thinning process. In some cases, forming an etch stop region 40 in the substrate 50 and/or the fins 66 can allow for improved planarity after performing the thinning process. In some embodiments, the removal rate of the thinning process may be reduced in the etch stop region 40 relative to the removal rate of other regions (e.g., overlying regions) of the substrate 50. In some embodiments, the etch stop region 40 may have a removal rate that is between about 55% and about 90% of the removal rate of other regions of the substrate 50, though other relative removal rates of the etch stop region 40 are possible. In some cases, increasing the concentration of impurities in the etch stop region 40 can decrease the removal rate of the etch stop region 40. For example, in some embodiments, the removal rate can be reduced by implanting impurities to a concentration of about 5×10¹⁸ atoms/cm³ or greater.

Reducing the removal rate of the thinning process in this manner can improve planarity by reducing dishing effects or pattern loading effects, for example. In some cases, forming an etch stop region 40 as described herein can allow for surface height variations of less than about 5 nm after thinning. In some cases, the techniques described herein can allow for surface height variations of less than about 5 nm across an entire die after thinning. Improving planarity in this manner can improve lithography, reduce feature size, improve reproducibility, improve uniformity, improve device performance, or improve yield. In some cases, an etch stop region 40 formed from two or more implantations (as described previously) can allow for a smoother or more gradual reduction of the removal rate during the thinning process, which can result in improved planarity from the thinning process.

In some embodiments, the thinning process is a chemical mechanical polish (CMP) process comprising a slurry having a pH in the range of about 10 to about 12. In some embodiments, the slurry comprises KOH or the like. In embodiments in which oxygen ions are implanted, the pH of the slurry may be in the range of about 5 to about 7. In embodiments in which nitrogen ions are implanted, the pH of the slurry may be in the range of about 4 to about 7. Other slurries are possible, which may have a pH other than these example ranges.

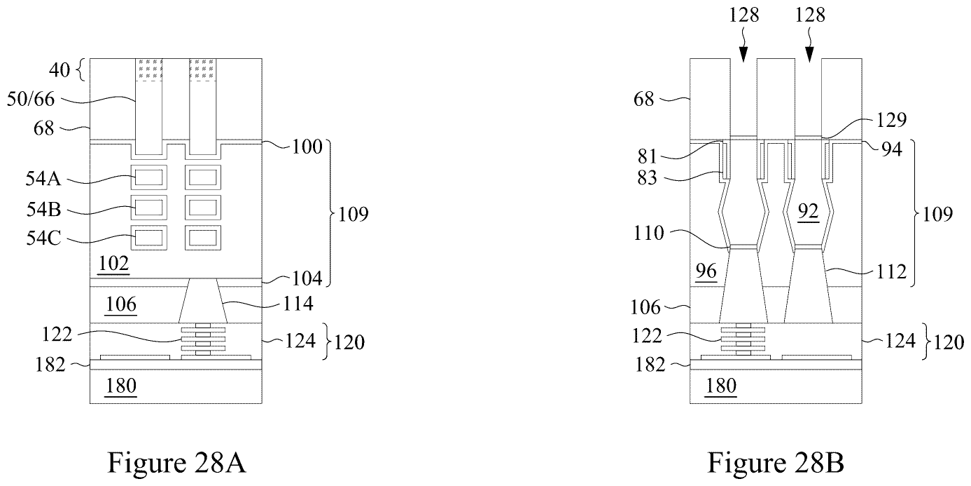

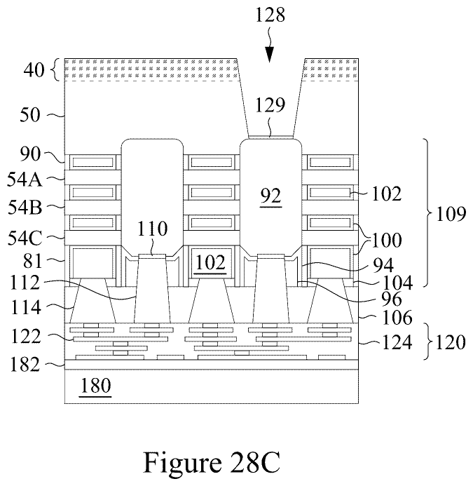

In FIGS. 28A through 28C, recesses 128 are formed in the substrate 50, and second silicide regions 129 are formed in the recesses 128. The recesses 128 may also be formed in the fins 66 and/or in the etch stop region 40, in some embodiments. The recesses 128 may be formed by etching the substrate 50 using a suitable etching process, such as an isotropic etching process (e.g., a wet etching process), an anisotropic etching process (e.g., a dry etching process), or the like. The etching process may be one that is selective to the material of the substrate 50. For example, the etching process may etch the material of the substrate 50 at a faster rate than the material of the STI regions 68, the gate dielectric layers 100, the epitaxial source/drain regions 92, the epitaxial materials 91, and/or the first inner spacers 90. The recesses 128 may expose sidewalls of the STI regions 68 and backside surfaces of the epitaxial source/drain regions 92. In other embodiments, portions of the fins 66 and/or the substrate 50 may be removed and replaced by a dielectric material (not shown) before forming the recesses 128, with the dielectric material being etched to form the recesses 128.

Second silicide regions 129 may then be formed in the recesses 128 on backsides of the epitaxial source/drain regions 92, in accordance with some embodiments. The second silicide regions 129 may be similar to the first silicide regions 110, described above with respect to FIGS. 23A through 23C. For example, the second silicide regions 129 may be formed of a like material and using a like process as the first silicide regions 110.

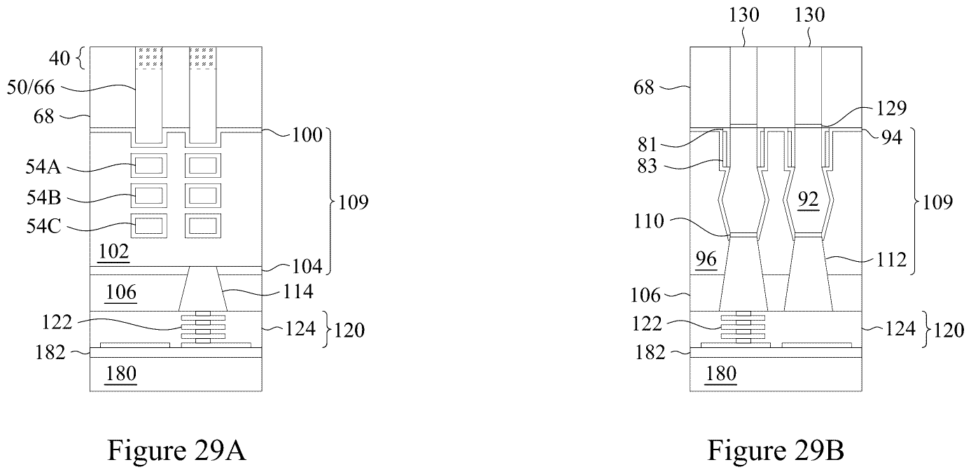

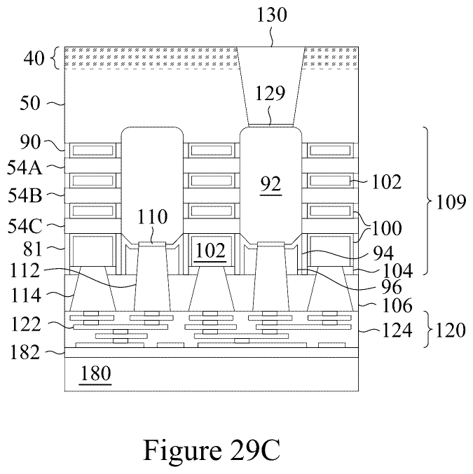

In FIGS. 29A through 29C, backside vias 130 are formed in the recesses 128, in accordance with some embodiments. The backside vias 130 may extend through the fins 66, the substrate 50, and/or the STI regions 68 and may be electrically coupled to the epitaxial source/drain regions 92 through the second silicide regions 129. The backside vias 130 may be similar to the source/drain contacts 112, described above with respect to FIGS. 24A through 24C. For example, the backside vias 130 may be formed of a like material and using a like process as the source/drain contacts 112. The backside vias 130 may include copper, a copper alloy, silver, gold, tungsten, cobalt, aluminum, nickel, ruthenium, or the like. A planarization process, such as a CMP, may be performed to remove excess portions of the backside vias 130, which excess portions are over top surfaces of the STI regions 68 and the substrate 50.

In FIGS. 30A through 30C, remaining portions of a backside interconnect structure 140 are formed over the backside vias 130, the fins 66, the substrate 50, and/or the STI regions 68. The backside interconnect structure 140 may be referred to as a backside interconnect structure because it is formed on a backside of the device layer 109 (e.g., a side of the device layer 109 opposite the side of the device layer 109 on which active devices are formed). In some embodiments, the backside interconnect structure 140 includes conductive lines 132, a dielectric layer 134, conductive features 136, dielectric layers 137, a redistribution layer 138, and a passivation layer 139. The dielectric layer 134 may be formed of materials and in a manner the same as or similar to the second ILD 106, described above with respect to FIGS. 22A through 22C.

The conductive lines 132 are formed in the dielectric layer 134. Forming the conductive lines 132 may include patterning recesses in the dielectric layer 134 using a combination of photolithography and etching processes, for example. A pattern of the recesses in the dielectric layer 134 may correspond to a pattern of the conductive lines 132. The conductive lines 132 are then formed by depositing a conductive material in the recesses. In some embodiments, the conductive lines 132 comprise a metal layer, which may be a single layer or a composite layer comprising a plurality of sub-layers formed of different materials. In some embodiments, the conductive lines 132 comprise copper, aluminum, cobalt, tungsten, titanium, tantalum, ruthenium, or the like. An optional diffusion barrier and/or optional adhesion layer may be deposited prior to filling the recesses with the conductive material. Suitable materials for the barrier layer/adhesion layer include titanium, titanium nitride, titanium oxide, tantalum, tantalum nitride, tantalum oxide, or the like. The conductive lines 132 may be formed using, for example, CVD, ALD, PVD, plating, or the like. The conductive lines 132 are electrically coupled to the epitaxial source/drain regions 92 through the backside vias 130 and the second silicide regions 129. A planarization process (e.g., a CMP, a grinding, an etch-back, or the like) may be performed to remove excess portions of the conductive lines 132 formed over the dielectric layer 134.

In some embodiments, the conductive lines 132 are backside power rails, which are conductive lines that electrically couple the epitaxial source/drain regions 92 to a reference voltage, a supply voltage, or the like. By placing the power rails on the backside of the semiconductor die, rather than on the front-side of the semiconductor die, advantages may be achieved. For example, a gate density of the nano-FETs and/or interconnect density of the front-side interconnect structure 120 may be increased. Further, the backside of the semiconductor die may accommodate wider power rails, reducing resistance and increasing efficiency of power delivery to the nano-FETs. For example, a width of the conductive lines 132 may be at least twice a width of first level conductive lines (e.g., the conductive features 122) of the front-side interconnect structure 120.

The remainder of the backside interconnect structure 140 may be similar to the front-side interconnect structure 120. For example, the backside interconnect structure 140 may be formed of materials and by processes the same as or similar to those of the front-side interconnect structure 120. The backside interconnect structure 140 may include stacked layers of conductive features 136 formed in stacked dielectric layers 137. The conductive features 136 may include conductive lines (e.g., for routing to and from subsequently formed contact pads and conductive connectors, such as external connectors). The conductive features 136 may include conductive vias that extend in the dielectric layers 137 to provide vertical interconnection between stacked layers of the conductive lines. The conductive features 136 may include one or more embedded passive devices, such as resistors, capacitors, inductors, or the like. The embedded passive devices may be integrated with the conductive lines 132 (e.g., the power rail) to provide circuits (e.g., power circuits) on the backside of the nano-FETs.

The redistribution layer 138 and the passivation layer 139 are formed over the conductive features 136 and the dielectric layers 137. The passivation layer 139 may include polymers such as PBO, polyimide, BCB, or the like. In some embodiments, the passivation layer 139 may include non-organic dielectric materials such as silicon oxide, silicon nitride, silicon carbide, silicon oxynitride, or the like. The passivation layer 139 may be deposited by, for example, CVD, PVD, ALD, or the like.

The redistribution layer 138 is formed through the passivation layer 139 to the conductive features 136. In some embodiments, the redistribution layer 138 may be used to provide input/output connections to other electrical components, such as, other device dies, redistribution structures, printed circuit boards (PCBs), motherboards, or the like. The redistribution layer 138 may be referred to as backside input/output pads that may provide signal, supply voltage, and/or ground connections to the nano-FETs. The redistribution layer 138 may be used to provide a heat dissipation path from the device layers 109 through the backside interconnect structure 140. The redistribution layer 138 may include one or more layers of copper, nickel, gold, or the like, which are formed by a plating process, or the like.

Embodiments may achieve advantages. For example, forming an implanted etch stop as described herein can reduce dishing, pattern loading, or surface height variation (e.g., step height) when thinning the backside of the substrate. In this manner, planarity of the thinned surface may be improved, which can improve subsequently performed lithographic processes. Device uniformity and yield may also be improved. The techniques described herein can allow for improved planarity over a large area, such as over the entire area of one or more semiconductor dies. The techniques described herein may allow for the formation of an etch stop and/or improved planarity without significant additional cost or processing. For example, defects introduced during the implantation of the etch stop impurities may be partially or fully removed using an anneal.

In accordance with an embodiment of the present disclosure, a method includes implanting impurities in a semiconductor substrate to form an etch stop region within the semiconductor substrate; forming a transistor structure on a front side of the semiconductor substrate; forming a front-side interconnect structure over the transistor structure; performing a thinning process on a back side of the semiconductor substrate to reduce a thickness of the semiconductor substrate, wherein the thinning process is slowed by the etch stop region; and forming a back-side interconnect structure over the back side of the semiconductor substrate. In an embodiment, the impurities include boron, aluminum, gallium, indium, or titanium. In an embodiment, the impurities are implanted using a dose in the range of 5×10¹⁴ cm⁻² to 2×10¹⁵ cm⁻². In an embodiment, the etch stop region has a concentration of impurities greater than range of about 5×10¹⁸ cm⁻³. In an embodiment, the removal rate of the thinning process within the etch stop region is between 55% and 90% of the removal rate for the semiconductor substrate outside of the etch stop region. In an embodiment, the etch stop region is separated from a front surface of the semiconductor substrate by a distance in the range of 40 nm to 60 nm. In an embodiment, a portion of the etch stop region remains after performing the thinning process. In an embodiment, the transistor structure includes a nano-FET.

In accordance with an embodiment of the present disclosure, a method includes performing an implantation process to form an implanted region of a substrate; forming a first transistor over the implanted region of the substrate; forming a first interconnect structure over a first side of the first transistor, wherein the first interconnect structure is electrically coupled to the first transistor; thinning the substrate, wherein the implanted region is exposed after the thinning of the substrate; and forming a second interconnect structure over a second side of the first transistor, wherein the second interconnect structure is electrically coupled to the first transistor. In an embodiment, the implantation process includes an energy in the range of 20 keV to 40 keV. In an embodiment, the implanted region has a height in the range of 100 nm to 300 nm. In an embodiment, the height of the implant region corresponds to the height of a portion of the implant region having an impurity concentration of 5×10¹⁸ cm⁻³ or greater. In an embodiment, the method includes forming an isolation region over the implanted region of the substrate, wherein the isolation region is exposed after the thinning of the substrate. In an embodiment, the method includes forming a via penetrating the implanted region to electrically contact the first transistor, wherein the second interconnect structure is formed over and electrically contacts the via. In an embodiment, the implantation process includes implanting oxygen ions.

In accordance with an embodiment of the present disclosure, a device includes a semiconductor fin including an implanted region at a first side of the semiconductor fin, wherein the implanted region has a first concentration of implanted impurities; an isolation region surrounding the semiconductor fin, wherein surfaces of the isolation region and the implanted region of the semiconductor fin are level; a source/drain region on a second side of the semiconductor fin; a via penetrating the semiconductor fin to electrically contact the source/drain region, wherein the via penetrates the implanted region; a first interconnect structure over the first side of the semiconductor fin, wherein the first interconnect structure is electrically connected to the via; and a second interconnect structure over the second side of the semiconductor fin. In an embodiment, the second interconnect structure is electrically connected to the source/drain region. In an embodiment, surfaces of the isolation region and the implanted region are level to within 5 nm. In an embodiment, the first concentration is greater than 5×10¹⁸ cm³. In an embodiment, the impurities include boron.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
performing an implantation process on a substrate to form a doped region below a top surface of the substrate, wherein the doped region is separated from the top surface of the substrate;
patterning the substrate to form a fin protruding from the doped region, wherein the fin comprises a portion of the doped region, wherein a portion of the fin is above the doped region;
forming a plurality of nanostructures on the fin;
patterning the fin to form a recess adjacent the plurality of nanostructures, wherein a bottom surface of the recess is above the doped region;
forming an epitaxial region in the recess, wherein the epitaxial region is separated from the doped region;
performing a planarization process on a bottom surface of the substrate, wherein the planarization process removes the portions of the doped region that are outside of the fin;
forming a contact extending through the fin to contact the epitaxial region; and
forming an interconnect structure on the fin and on the contact.

2. The method of claim 1, wherein doped region has a thickness in a range of 100 nm to 300 nm.

3. The method of claim 1, wherein a distance from the doped region to a top surface of the substrate is in a range of 40 nm to 60 nm.

4. The method of claim 1, wherein the implantation process comprises a dosage in a range of 5×10¹⁴ cm⁻² to 2×10¹⁵ cm⁻².

5. The method of claim 1, wherein, after performing the planarization process, the fin has a height in a range of 40 nm to 60 nm.

6. The method of claim 1, further comprising forming an isolation region on the doped region and around the fin, wherein after performing the planarization process, top surfaces of the isolation region and the doped region are level.

7. The method of claim 1, wherein the planarization process partially removes the fin.

8. The method of claim 1, wherein a distance from the epitaxial region to the doped region is greater than a thickness of the doped region.

9. A method comprising:
performing a first implantation process on a substrate to form an implanted region of the substrate, wherein the implanted region is between an upper region of the substrate and a lower region of the substrate, wherein the implanted region has a dopant concentration greater than the upper region and the lower region;
forming a transistor on the upper region of the substrate, wherein the transistor is separated from the implanted region by the upper region;
performing a planarization process on the substrate to fully remove the lower region and at least partially remove the implanted region, wherein the planarization process removes material in the lower region at a greater rate than the planarization process removes material in the implanted region; and
forming an interconnect structure on the substrate, wherein the interconnect structure is electrically connected to the transistor, wherein the interconnect structure is separated from the transistor by the upper region.

10. The method of claim 9, wherein the removal rate of the implanted region is between 55% and 90% of the removal rate of the lower region.

11. The method of claim 9, wherein the implanted region comprises oxygen.

12. The method of claim 9, wherein the transistor comprises a plurality of nanostructures.

13. The method of claim 9, wherein the planarization process uses a slurry comprising KOH.

14. The method of claim 9, wherein the planarization process fully removes the implanted region.

15. The method of claim 9, wherein the interconnect structure physically contacts the implanted region.

16. The method of claim 9 further comprising performing a second implantation process on the implanted region of the substrate.

17. A device comprising:
a first interconnect structure;
a semiconductor fin on the first interconnect structure, wherein a lower portion of the semiconductor fin has a greater dopant concentration than an upper portion of the semiconductor fin, wherein a vertical height of the lower portion is less than a vertical height of the upper portion, wherein the lower portion physically contacts the first interconnect structure;
an isolation region on the first interconnect structure and surrounding the semiconductor fin, wherein surfaces of the lower portion and the isolation region are level;
a source/drain region in the upper portion;
a plurality of nanostructures over the upper portion; and
a gate structure around the plurality of nanostructures and over the upper portion.

18. The device of claim 17, wherein upper portion extends between source/drain and lower portion.

19. The device of claim 17 further comprising a via extending from the first interconnect structure to the source/drain region.

20. The device of claim 17, wherein the lower portion has a dopant concentration in a range of 10¹⁸ cm⁻³ to 10²⁰ cm⁻³.
